(19) United States
(12) Patent Application Publication
(10) Pub. No.: US 2026/0268850 A1
(43) Pub. Date: Sep. 10, 2026

(54) PIXEL AND ELECTRONIC DEVICE INCLUDING THE SAME

(71) Applicant: Samsung Display Co., Ltd., Yongin-si (KR)

(72) Inventors: Jaekeun Lim, Yongin-si (KR); Jinwook Yang, Yongin-si (KR); Haekwan Seo, Yongin-si (KR)

(21) Appl. No.: 19/555,966

(22) Filed: Mar. 4, 2026

(30) Foreign Application Priority Data
Mar. 10, 2025 (KR) 10-2025-0030598

(51) Int. Cl. G09G 3/3233

(52) U.S. Cl. CPC G09G 3/3233; G09G 2300/0819; G09G 2300/0852; G09G 2300/0861; G09G 2310/08; G09G 2320/0233

(57) ABSTRACT

A display device includes a pixel. The pixel includes a first transistor including a first terminal connected to a first voltage line, a second transistor connected to a data line and a gate of the first transistor, a third transistor connected to the gate of the first transistor and a second voltage line, a fourth transistor including a first terminal connected to a second terminal of the first transistor, a first capacitor connected to the gate of the first transistor and a second terminal of the fourth transistor, and a second capacitor connected to the second terminal of the fourth transistor and a voltage source supplying a constant voltage.

This application claims priority to Korean Patent Application No. 10-2025-0030598, filed on Mar. 10, 2025, and all the benefits accruing therefrom under 35 U.S.C. §119, the content of which in its entirety is herein incorporated by reference.

### BACKGROUND

### 1. Field

Embodiments relate to a pixel, a display device, and an electronic device including the same.

### 2. Description of the Related Art

Recently, the usage of display devices is being diversified. In addition, as display devices have become thinner and lighter, their range of use becomes gradually extended.

As a display device is variously utilized, there may be various methods of designing the shape of a display device, and also, functions that may be combined or associated with a display device have increased.

### SUMMARY

Embodiments include a display device of relatively high resolution. However, such an objective is just an example, and the scope of the disclosure is not limited thereto.

Additional features will be set forth in part in the description which follows and, in part, will be apparent from the description, or may be learned by practice of the presented embodiments of the disclosure.

In an embodiment of the disclosure, a pixel includes a first transistor including a gate, a first terminal connected to a first voltage line, and a second terminal, a second transistor connected to a data line and a gate of the first transistor, a third transistor connected to the gate of the first transistor and a second voltage line, a fourth transistor including a first terminal connected to a second terminal of the first transistor, and a second terminal, a fifth transistor connected to the second terminal of the first transistor and the first voltage line, a first capacitor connected to the gate of the first transistor and a second terminal of the fourth transistor, and a second capacitor connected to the second terminal of the fourth transistor and a voltage source supplying a constant voltage.

In an embodiment, the first transistor may include an N-channel transistor.

In an embodiment, a gate signal supplied to a gate of the second transistor and a gate signal supplied to a gate of the fifth transistor may be the same to each other.

In an embodiment, a gate signal supplied to a gate of the fifth transistor may have a same waveform as a gate signal supplied to a gate of the second transistor, and may be a signal shifted forward or backward in time from a gate signal supplied to the gate of the second transistor.

In an embodiment, the constant voltage supplied by the voltage source to which the second capacitor is connected may be a voltage supplied to the first voltage line.

In an embodiment, the constant voltage supplied by the voltage source to which the second capacitor is connected may be a voltage supplied to the second voltage line.

In an embodiment, during a data-write period in which the second transistor is turned on and a data signal from the data line is transmitted to the gate of the first transistor, the fourth transistor may be turned off, and before the pixel emits light, the fifth transistor may be turned on and the constant voltage may be transmitted to the second terminal of the first transistor.

In an embodiment, the pixel may further include a sixth transistor connected to a light-emitting element and a third voltage line, and a seventh transistor connected to the second terminal of the fourth transistor and the light-emitting element.

In an embodiment, a gate signal supplied to a gate of the fourth transistor and a gate signal supplied to a gate of the sixth transistor may be the same to each other.

In an embodiment, the constant voltage supplied by the voltage source to which the second capacitor is connected may be a voltage supplied to the third voltage line.

In an embodiment, one electrode of the light-emitting element may be connected to the seventh transistor, and the constant voltage supplied by the voltage source to which the second capacitor is connected may be a voltage supplied to another electrode of the light-emitting element.

In an embodiment of the disclosure, a pixel includes a first transistor including a gate, a first terminal connected to a first voltage line, and a second terminal, a second transistor connected to a data line and a gate of the first transistor, a third transistor connected to the gate of the first transistor and a second voltage line, a fourth transistor including a gate, a first terminal connected to a second terminal of the first transistor, and a second terminal, a first capacitor connected to the gate of the first transistor and a second terminal of the fourth transistor, a second capacitor connected to the second terminal of the fourth transistor and a voltage source supplying a constant voltage, and a third capacitor connected to the second terminal of the first transistor, and a gate of the second transistor or a gate of the fourth transistor.

In an embodiment, the first transistor may be an N-channel transistor.

In an embodiment, the constant voltage supplied by the voltage source to which the second capacitor is connected may be a voltage supplied to the first voltage line.

In an embodiment, the constant voltage supplied by the voltage source to which the second capacitor is connected may be a voltage supplied to the second voltage line.

In an embodiment, the third capacitor may raise a voltage of the second terminal of the first transistor according to a change in a voltage level of a gate signal supplied to a gate of the second transistor or a gate signal supplied to the gate of the fourth transistor, and during a data-write period in which the second transistor is turned on and a data signal from the data line is transmitted to the gate of the first transistor, the first transistor may be turned off.

In an embodiment, the pixel may further include a sixth transistor connected to a light-emitting element and a third voltage line, and a seventh transistor connected to the second terminal of the fourth transistor and the light-emitting element.

In an embodiment of the disclosure, an electronic device includes a processor, a controller configured to receive an on-operation signal from a processor and output a control signal based on the on-operation signal, a gate driving circuit configured to receive the control signal and sequentially output at least one gate signal, and a display panel in which a plurality of pixels are arranged, each of the plurality of pixels receiving the at least one gate signal. Each of the plurality of pixels may include a first transistor including a gate, a first terminal connected to a first voltage line, and a second terminal, a second transistor connected to a data line and a gate of the first transistor, a third transistor connected to the gate of the first transistor and a second voltage line, a fourth transistor including a first terminal connected to a second terminal of the first transistor, and a second terminal, a control element connected to the second terminal of the first transistor, a first capacitor connected to the gate of the first transistor and a second terminal of the fourth transistor, and a second capacitor connected to the second terminal of the fourth transistor and a voltage source supplying a constant voltage.

In an embodiment, the control element may include a fifth transistor connected to the second terminal of the first transistor and the first voltage line.

In an embodiment, the control element may include a third capacitor connected to the second terminal of the first transistor, and a gate of the second transistor or a gate of the fourth transistor.

### BRIEF DESCRIPTION OF THE DRAWINGS

The above and other features and advantages of illustrative embodiments of the disclosure will be more apparent from the following description taken in conjunction with the accompanying drawings, in which:

FIGS. 1A and 1B are schematic views of an embodiment of a display device;

FIG. 2 is a schematic view of an embodiment of the display device;

FIG. 3 is a schematic view of an embodiment of a portion of a gate driving circuit of FIG. 2;

FIG. 4 is a schematic equivalent circuit diagram of an embodiment of a pixel;

FIG. 5 is a timing diagram to explain an embodiment of an operation of a pixel of FIG. 4;

FIG. 6 is a diagram to explain an operation of a pixel during a third period;

FIG. 7 is a schematic equivalent circuit diagram of an embodiment of a pixel;

FIG. 8 is a schematic equivalent circuit diagram of an embodiment of a pixel;

FIG. 9 is a schematic equivalent circuit diagram of an embodiment of a pixel;

FIGS. 10A and 10B are schematic equivalent circuit diagrams of an embodiment of a pixel;

FIGS. 11A to 11C are schematic equivalent circuit diagrams of an embodiment of a pixel;

FIGS. 12A and 12B are schematic equivalent circuit diagrams of an embodiment of a pixel;

FIG. 13 is a timing diagram to explain an operation of pixels shown in FIGS. 12A and 12B;

FIG. 14 is a schematic equivalent circuit diagram of an embodiment of a pixel;

FIG. 15 is a timing diagram to explain an operation of a pixel shown in FIG. 14;

FIGS. 16A to 16C are schematic equivalent circuit diagrams of an embodiment of a pixel;

FIG. 17 is a schematic equivalent circuit diagram of an embodiment of a pixel;

FIG. 18 is a schematic equivalent circuit diagram of an embodiment of a pixel;

FIG. 19 is a timing diagram to explain an operation of of a pixel shown in FIG. 18;

FIG. 20 is a diagram showing an embodiment of a brightness deviation of pixels;

FIG. 21 is a block diagram of an embodiment of an electronic device; and

FIG. 22 is a schematic view of an embodiment of electronic devices.

### DETAILED DESCRIPTION

Reference will now be made in detail to embodiments, illustrative embodiments of which are illustrated in the accompanying drawings, wherein like reference numerals refer to like elements throughout. In this regard, the illustrated embodiments may have different forms and should not be construed as being limited to the descriptions set forth herein. Accordingly, the embodiments are merely described below, by referring to the drawing figures, to explain features of the description. As used herein, the term "and/or" includes any and all combinations of one or more of the associated listed items. Throughout the disclosure, the expression "at least one of a, b, and c" indicates only a, only b, only c, both a and b, both a and c, both b and c, all of a, b, and c, or variations thereof.

As the disclosure allows for various changes and numerous embodiments, illustrative embodiments will be illustrated in the drawings and described in the detailed description. Effects and features of the disclosure, and methods for achieving them will be clarified with reference to embodiments described below in detail with reference to the drawings. However, the disclosure is not limited to embodiments described below and may be implemented in various forms.

In embodiments below, such terms as "first" and "second" are not used in a limited meaning and are used for the purpose of distinguishing one element from another.

In embodiments below, the singular expressions include the plural expressions unless the context clearly indicates otherwise.

In embodiments below, the terms, such as “comprise” or “have”, specify the presence of stated features or elements described in the specification but do not preclude the possibility of the addition of one or more other features or elements.

In the specification, "A and/or B" means A or B, or A and B. In the specification, "at least one of A and B" means A or B, or A and B.

In embodiments below, when it is described that X is connected to Y, X may be electrically connected to Y, X may be functionally connected to Y, or X may be physically connected to Y. Here, X and Y may be objects (e.g., apparatuses, elements, circuits, wirings, electrodes, terminals, conductive layers, films (layers), and the like). Accordingly, X and Y are not limited to preset connection relationships and connection relationships shown and made in the drawings and the detailed description, but may include connection relationships other than the connection relationships shown and made in the drawings and the detailed description.

For example, the case where X and Y are electrically connected to each other may include the case where X and Y are in direct contact and electrically connected with each other, and the case where at least one element (e.g., a switch, a transistor, a capacitor, an inductor, a resistor, a diode, and the like) that enables electrical connection between X and Y is connected between X and Y.

In embodiments below, "ON" used in association with an element state may denote an active state of an element, and "OFF" may denote an inactive state of an element. "ON" used in association with a signal received by an element may denote a signal activating the element, and "OFF" may denote a signal inactivating the element. An element may be activated by a high-level voltage or a low-level voltage. As an example, a P-channel transistor (a P-type transistor) may be activated by a low-level voltage, and an N-channel transistor (an N-type transistor) may be activated by a high-level voltage. Accordingly, it should be understood that "ON" voltages for a P-type transistor and an N-type transistor are opposite (low vs. high) voltage levels.

In embodiments below, an x direction, a y direction, and a z direction are not limited to directions of three axes of the rectangular coordinate system, and may be interpreted in a broader sense. For example, the x direction, the y direction, and the z direction may be perpendicular to one another, or may represent different orientations that are not perpendicular to one another.

Sizes of elements in the drawings may be exaggerated or reduced for convenience of explanation. As an example, the size and thickness of each element shown in the drawings are arbitrarily represented for convenience of description, and thus, the disclosure is not necessarily limited thereto.

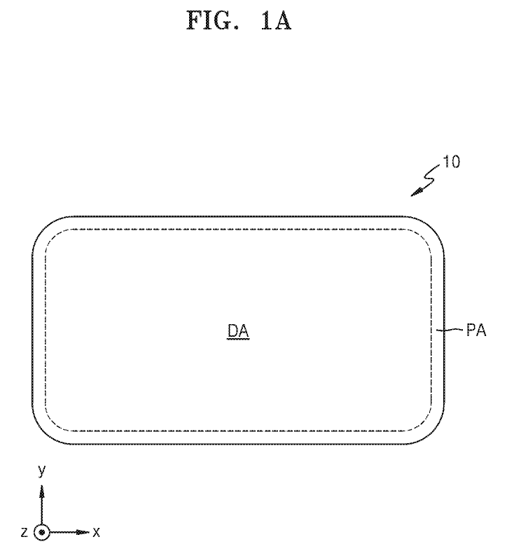

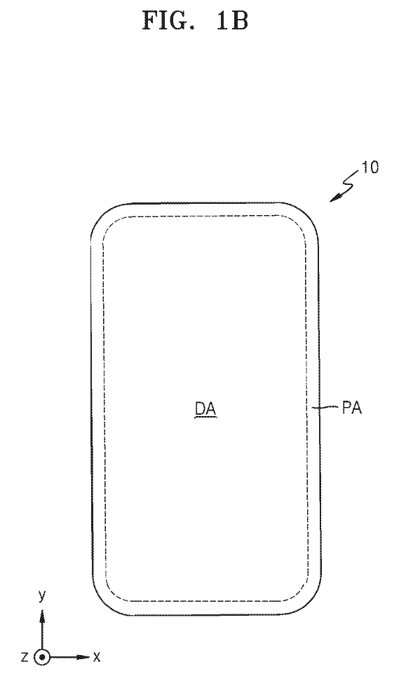

FIGS. 1A and 1B are schematic views of an embodiment of a display device 10.

Referring to FIGS. 1A and 1B, the display device 10 may include a display area DA configured to display images and a peripheral area PA outside the display area DA. The display area DA may be surrounded by the peripheral area PA entirely.

In a plan view, the display area DA may be provided in a quadrangular shape, e.g., rectangular shape. In another embodiment, the display area DA may be provided in a polygonal shape such as a triangle, a pentagon, a hexagon, or the like, a circular shape, an elliptical shape, an irregular shape, or the like. The display area DA may have an edge with round corners. In an embodiment, as shown in FIG. 1A, the display device 10 may have the display area DA of a shape in which the length thereof in a y direction is less than the length thereof in an x direction. In another embodiment, as shown in FIG. 1B, the display device 10 may have the display area DA of a shape in which the length thereof in the x direction is less than the length thereof in the y direction.

The display device 10 displays moving images or still images and may provide users with visual information. The display device 10 in an embodiment may be an organic light-emitting display apparatus, an inorganic light-emitting display apparatus, or a quantum-dot light-emitting display apparatus.

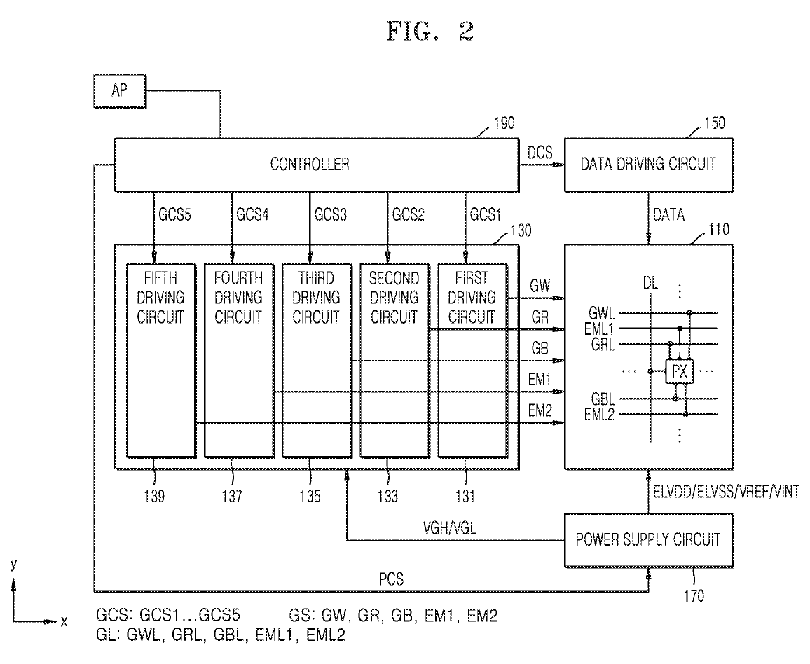

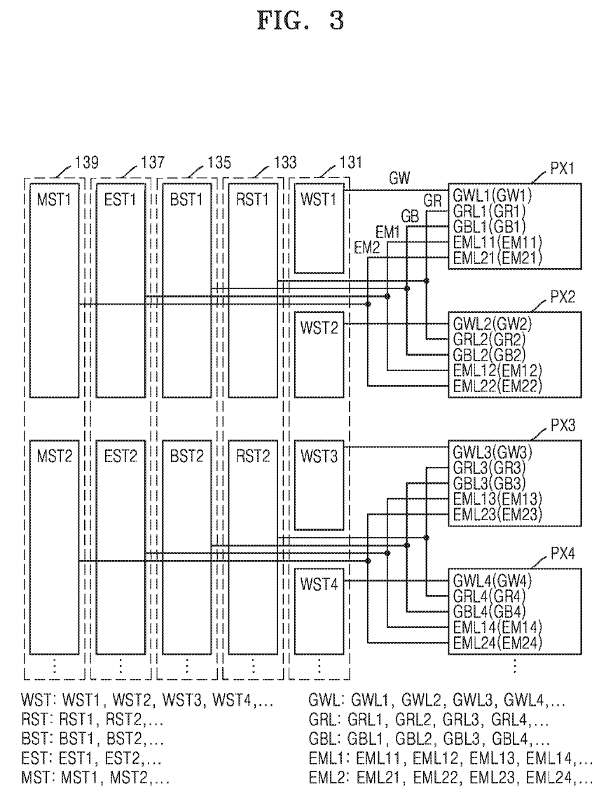

FIG. 2 is a schematic view of an embodiment of the display device 10. FIG. 3 is a schematic view of a portion of a gate driving circuit of FIG. 2.

Referring to FIG. 2, the display device 10 may include a display panel 110. The display panel 110 may include a substrate, and a plurality of gate lines GL, a plurality of data lines DL, and a plurality of pixels PX connected thereto may be disposed in the display area DA of the substrate. The plurality of pixels PX may be repeatedly arranged in a first direction (the x direction, a row direction) and a second direction (the y direction, a column direction). Each of the plurality of pixels PX may include an organic light-emitting element (e.g., organic light-emitting diode) as a display element. The organic light-emitting element may be connected to a pixel circuit. The pixel circuit may include a plurality of transistors and at least one capacitor. Each of the pixels PX may be connected to a corresponding gate line among the plurality of gate lines GL and a corresponding data line among the plurality of data lines DL.

The gate lines GL may each extend in the x direction (a row direction) and be connected to the pixels PX disposed in the same row. The gate lines GL may transmit a gate signal to the pixels PX in the same row. In an embodiment, the gate lines GL may include first gate lines GWL, second gate lines GRL, third gate lines GBL, fourth gate lines EML1, and fifth gate lines EML2, and each of the first gate lines GWL, the second gate lines GRL, the third gate lines GBL, the fourth gate lines EML1, and the fifth gate lines EML2 may be disposed in each row.

The data lines DL may each extend in the y direction (a column direction) and be connected to the pixels PX disposed in the same column. The data lines DL may each transmit a data signal to each of the pixels PX in the same column in synchronization with a gate signal.

In the peripheral area PA (a non-display area) outside the display area DA of the display panel 110, various conductive lines configured to transmit electrical signals to be applied to the display area DA, outer driving circuits electrically connected to the pixel circuits, and pads to which a printed circuit board or a driver integrated circuit (“IC”) chip is attached may be disposed. The outer driving circuits may include a gate driving circuit 130, a data driving circuit 150, a power supply circuit 170, and a controller 190.

In an embodiment, the gate driving circuit 130, the data driving circuit 150, the power supply circuit 170, and the controller 190 as driving chips may be disposed (e.g., mounted) on the display panel 110. The data driving circuit 150, the power supply circuit 170, and the controller 190 may each be formed as separate IC chips, respectively, or one IC chip, and disposed on a flexible printed circuit board (“FPCB”) electrically connected to a pad disposed on one side of the substrate configuring the display panel 110. In another embodiment, the data driving circuit 150, the power supply circuit 170, and the controller 190 may be directly disposed on the substrate by using a chip-on-glass (“COG”) or chip-on-plastic (“COP”) method.

In an embodiment, a portion or all of the gate driving circuit 130 may be directly formed in a peripheral area PA of the substrate during a process of forming a transistor configuring a pixel circuit in the display area of the substrate. The gate driving circuit 130 may include an amorphous silicon thin-film transistor (“TFT”) gate driver circuit (“ASG”), a low temperature polycrystalline silicon (“LTPS”) TFT gate driver circuit, or an oxide semiconductor TFT gate (“OSG”) driver circuit embedded in the display panel 110.

The gate driving circuit 130 may be connected to the plurality of gate lines GL, configured to generate gate signals in response to gate driving control signals GCS from the controller 190, and sequentially supply the gate signals GS to the gate lines GL. The gate line GL may be connected to a gate of a transistor included in the pixel PX, and a gate signal may be a gate control signal controlling the turning on or turning off of a transistor connected to the gate line GL. A gate signal GS may include a gate-on voltage by which a transistor may be turned on, and a gate-off voltage by which a transistor may be turned off. In an embodiment, a gate-on voltage may be a high-level voltage VGH, and a gate-off voltage may be a low-level voltage VGL. In an embodiment, a gate driving control signal GCS may include a start signal and a plurality of clock signals. In an embodiment, the gate driving circuit 130 may be disposed on the left and/or right of the display area DA of the substrate.

The data driving circuit 150 may be connected to the plurality of data lines DL and configured to generate data signals DATA in response to a data driving control signal DCS from the controller 190. The data signal DATA may be transmitted to the pixel circuits of the pixels PX through the data line DL. The data signals DATA input to the data lines DL may be input to the pixels PX to which gate signals are input. The data driving circuit 150 may convert input image data into a data signal DATA of a voltage or current form, wherein the input image data has a grayscale and is input from the controller 190. In an embodiment, a data driving control signal DCS may include a start signal and a plurality of clock signals.

The power supply circuit 170 may generate signals (voltages and currents) desired for driving the pixels PX, in response to a power driving control signal PCS from the controller 190.

In the case where the display device 10 is an organic light-emitting display device, the power supply circuit 170 may supply a first driving voltage ELVDD and a second driving voltage ELVSS. The first driving voltage ELVDD may be applied to the pixel circuits of the pixel PX through a driving voltage line disposed in the display area DA, and the second driving voltage ELVSS may be applied to an opposite electrode of the display element. The first driving voltage ELVDD may be a high-level voltage provided to one terminal of a driving transistor connected to a first electrode (a pixel electrode or an anode) of the organic light-emitting element of each pixel PX. The second driving voltage ELVSS may be a low-level voltage provided to a second electrode (an opposite electrode or a cathode) of the organic light-emitting element. The first driving voltage ELVDD and the second driving voltage ELVSS may be driving voltages configured to allow the plurality of pixels PX to emit light. The power supply circuit 170 may generate a reference voltage VREF and an initialization voltage VINT and supply the same to the pixels PX.

The power supply circuit 170 may generate a high-level voltage VGH and a low-level voltage VGL and supply the same to the gate driving circuit 130.

The controller 190 may generate a gate driving control signal GCS, a data driving control signal DCS, and a power driving control signal PCS based on signals input from the outside. The controller 190 may supply a gate driving control signal GCS to the gate driving circuit 130, supply a data driving control signal DCS to the data driving circuit 150, and supply a power driving control signal PCS to the power supply circuit 170.

In an embodiment, the display device 10 may be connected to a processor of an electronic device. The processor may include an application processor (“AP”). The controller 190 may receive an on-operation signal, e.g., a power-on signal and/or an operation flag signal, from the AP. When the electronic device is powered on or awakened from a sleep mode by a user, the controller 190 may receive an on-operation signal from the AP, generate a gate driving control signal GCS, a data driving control signal DCS, and a power driving control signal PCS based on the on-operation signal, and output the same.

The pixel circuit of the pixel PX of the display panel 110 may include a driving transistor and at least one switching transistor, wherein the driving transistor outputs a source-drain current determined according to a gate-source voltage Vgs, and the switching transistor is turned on/turned off according to a gate-source voltage, substantially a gate voltage.

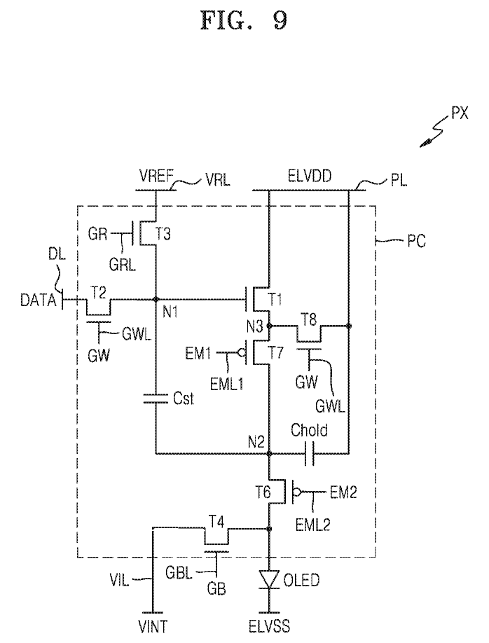

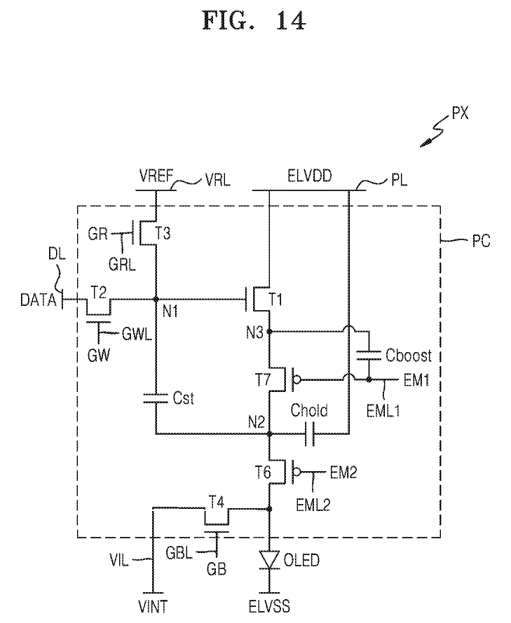

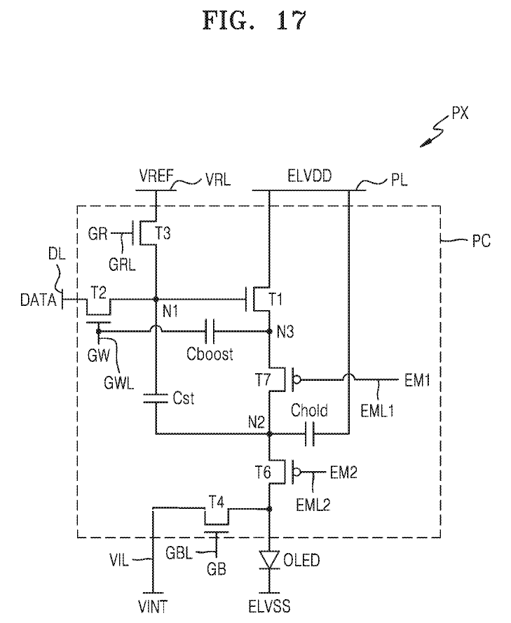

In an embodiment, the pixel circuit of the pixel PX may include the driving transistor connected to a first voltage line that receives the first driving voltage ELVDD, a first switching transistor connected to the data line DL and a gate of the driving transistor, a second switching transistor connected to the gate of the driving transistor and a reference voltage line that receives the reference voltage VREF, a third switching transistor connected to a first terminal and/or a second terminal of the driving transistor, a control element connected to the second terminal of the driving transistor, a first capacitor connected to the gate of the driving transistor and a second terminal of the third switching transistor, and a second capacitor connected to the second terminal of the third switching transistor and a voltage source that supplies a constant voltage. In an embodiment, as described below with reference to FIG. 9, the control element may be a fourth switching transistor connected to the second terminal of the driving transistor and the driving voltage line. In an embodiment, as described below with reference to FIGS. 14 and 17, the control element may be a third capacitor connected to the second terminal of the driving transistor, and a gate of the first switching transistor or a gate of the third switching transistor.

In an embodiment, the pixel circuit of the pixel PX may further include a fifth switching transistor connected to a light-emitting element and an initialization voltage line that receives the initialization voltage VINT, and a sixth switching transistor connected to a second terminal of the third switching transistor and the light-emitting element.

The gate driving circuit 130 may include a first driving circuit 131, a second driving circuit 133, a third driving circuit 135, a fourth driving circuit 137, and a fifth driving circuit 139.

The first driving circuit 131 may be connected to a plurality of first gate lines GWL and configured to sequentially supply first gate signals GW to the first gate lines GWL according to a first control signal GCS1. The second driving circuit 133 may be connected to a plurality of second gate lines GRL and configured to sequentially supply second gate signals GR to the second gate lines GRL according to a second control signal GCS2. The third driving circuit 135 may be connected to a plurality of third gate lines GBL and configured to sequentially supply third gate signals GB to the third gate lines GBL according to a third control signal GCS3. The fourth driving circuit 137 may be connected to a plurality of fourth gate lines EML1 and configured to sequentially supply fourth gate signals EM1 to the fourth gate lines EML1 according to a fourth control signal GCS4. The fifth driving circuit 139 may be connected to a plurality of fifth gate lines EML2 and configured to sequentially supply fifth gate signals EM2 to the fifth gate lines EML2 according to a fifth control signal GCS5.

Referring to FIG. 3, each of the first driving circuit 131, the second driving circuit 133, the third driving circuit 135, the fourth driving circuit 137, and the fifth driving circuit 139 may include a plurality of stages, and each stage may receive at least one clock signal and at least one voltage signal (e.g., a high-level voltage VGH and a low-level voltage VGL) and generate a corresponding gate signal.

The first driving circuit 131 may include a plurality of stages WST1, WST2, WST3, WST4,… that are sequentially connected to each other, and each of the plurality of stages WST1, WST2, WST3, WST4,… may correspond to each row of the display panel 110. Each of the plurality of stages WST1, WST2, WST3, WST4,… may generate a first gate signal GW (e.g., first gat signals GW1, GW2, GW3, GW4, …) and output the same to a first gate line GWL (e.g., first gate lines GWL1, GWL2, GWL3, GWL4, …) in a corresponding row (e.g., GWL1 for a first pixel PX1 in a first row, GWL2 for a second pixel PX2 in a second row, GWL3 for a third pixel PX3 in a third row and GWL4 for a fourth pixel PX4 in a fourth row).

First gate signals GW output from the plurality of stages WST1, WST2, WST3, WST4,…may be sequentially phase-shifted. In an embodiment, the first gate signals GW may be sequentially output with their phases shifted at intervals of 1 horizontal period H. First gate signals GW next (adjacent) to each other may partially overlap each other. In an embodiment, a first gate signal GW1 of a gate-on voltage output from a first stage WST1, and a first gate signal GW2 of a gate-on voltage output from a second stage WST2 may partially overlap each other. The number of stages of the first driving circuit 131 may be equal to the number of rows or the number of first gate lines GWL.

The second driving circuit 133 may include a plurality of stages RST1, RST2,... that are sequentially connected, and each of the plurality of stages RST1, RST2,… may correspond to two rows (a pair of rows) of the display panel 110. Each of the plurality of stages RST1, RST2,… may generate a second gate signal GR (e.g., second gate signals GR1, GR2, GR3, GR4, …) and output the same to second gate lines GRL (e.g., second gate lines GRL1, GRL2, GRL3, GRL4, …) in two corresponding rows. In an embodiment, the second gate signal GR may be simultaneously supplied to two second gate lines GRL respectively disposed in two rows.

Second gate signals GR output from the plurality of stages RST1, RST2,… may be sequentially phase-shifted. In an embodiment, the second gate signals GR may be sequentially output with their phases shifted at intervals of 2 horizontal periods H. The number of stages RST of the second driving circuit 133 may be 1/2 of the number of rows or 1/2 of the number of second gate lines GRL.

The third driving circuit 135 may include a plurality of stages BST1, BST2,... that are sequentially connected to each other, and each of the plurality of stages BST1, BST2,… may correspond to two rows (a pair of rows) of the display panel 110. Each of the plurality of stages BST1, BST2,… may generate a third gate signal GB (e.g., third gate signals GB1, GB2, GB3, GB4, …) and output the same to third gate lines GBL (e.g., third gate lines GBL1, GBL2, GBL3, GBL4, …) in corresponding two rows. In an embodiment, the third gate signal GB may be simultaneously supplied to two third gate lines GBL respectively disposed in two rows.

Third gate signals GB output from the plurality of stages BST1, BST2,.. may be sequentially phase-shifted. In an embodiment, the third gate signals GB may be sequentially output with their phases shifted at intervals of 2 horizontal periods H. The number of stages BST of the third driving circuit 135 may be 1/2 of the number of rows or 1/2 of the number of third gate lines GBL.

The fourth driving circuit 137 may include a plurality of stages EST1, EST2,... that are sequentially connected to each other, and each of the plurality of stages EST1, EST2,… may correspond to two rows (a pair of rows) of the display panel 110. Each of the plurality of stages EST1, EST2,… may generate a fourth gate signal EM1 (e.g., fourth gate signals EM11, EM12, EM13, EM14, …) and output the same to fourth gate lines EML1 (e.g., fourth gate lines EML11, EML12, EML13, EML14, …) in two corresponding rows. In an embodiment, the fourth gate signal EMb may be simultaneously supplied to two fourth gate lines EML1 respectively disposed in two rows.

Fourth gate signals EM1 output from the plurality of stages EST1, EST2,… may be sequentially phase-shifted. In an embodiment, the fourth gate signals EM1 may be sequentially output with their phases shifted at intervals of 2 horizontal periods H. The number of stages EST of the fourth driving circuit 137 may be 1/2 of the number of rows or 1/2 of the number of fourth gate lines EML1.

The fifth driving circuit 139 may include a plurality of stages MST1, MST2,... that are sequentially connected to each other, and each of the plurality of stages MST1, MST2,… may correspond to two rows (a pair of rows) of the display panel 110. Each of the plurality of stages MST1, MST2,… may generate a fifth gate signal EM2 (e.g., fifth gate signals EM21, EM22, EM23, EM24, …) and output the same to fifth gate lines EML2 (e.g., fifth gate lines EML21, EML22, EML23, EML24, …) in corresponding two rows. In an embodiment, the fifth gate signal EM2 may be simultaneously supplied to two fifth gate lines EML2 respectively disposed in two rows.

Fifth gate signals EM2 output from the plurality of stages MST1, MST2,… may be sequentially phase-shifted. In an embodiment, the fifth gate signals EM2 may be sequentially output with their phases shifted at intervals of 2 horizontal periods H. The number of stages MST of the fifth driving circuit 139 may be 1/2 of the number of rows or 1/2 of the number of fifth gate lines EML2.

The positions of the first driving circuit 131, the second driving circuit 133, the third driving circuit 135, the fourth driving circuit 137, and the fifth driving circuit 139 are not limited to the positions shown in FIGS. 2 and 3. In an embodiment, the positions of some of the driving circuits may be changed due to a change in some of gate signals supplied to the pixels PX. Although it is shown in FIGS. 2 and 3 that the gate driving circuit 130 (the first driving circuit 131, the second driving circuit 133, the third driving circuit 135, the fourth driving circuit 137 and the fifth driving circuit 139) is disposed on the left, the same gate driving circuit 130 may be further disposed on the right or the gate driving circuit 130 may be disposed only on the right. However, various modifications may be made.

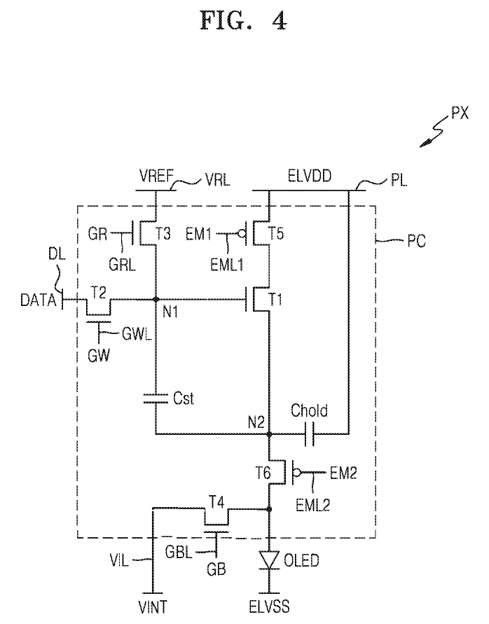

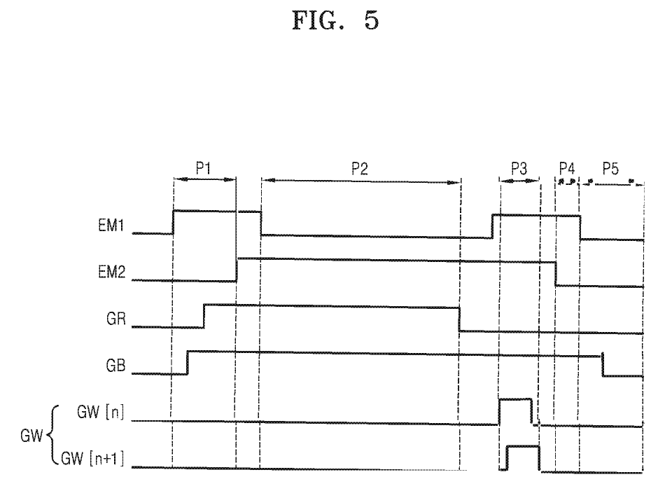

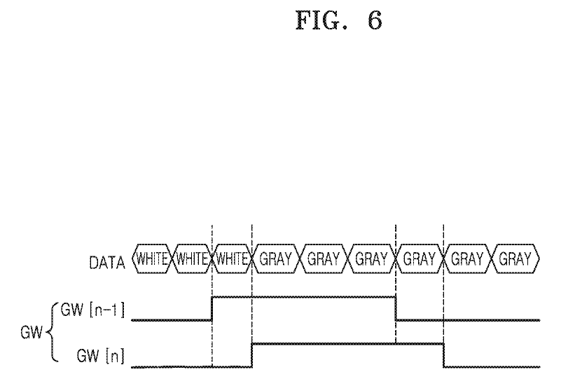

FIG. 4 is a schematic equivalent circuit diagram of an embodiment of the pixel PX. FIG. 5 is a timing diagram to explain an operation of an embodiment of the pixel PX of FIG. 4. FIG. 6 is a diagram to explain an operation of the pixel PX during a third period.

Referring to FIG. 4, the pixel PX may include a pixel circuit PC and an organic light-emitting element (e.g., organic light-emitting diode) OLED as a display element connected to the pixel circuit PC.

The pixel circuit PC may include first to sixth transistors T1, T2, T3, T4, T5, and T6, a first capacitor Cst, and a second capacitor Chold. Signal lines connected to the pixel circuit PC may include the data line DL, the first gate line GWL, the second gate line GRL, the third gate line GBL, the fourth gate line EML1, the fifth gate line EML2, a driving voltage line (also referred to as a first voltage line) PL, a reference voltage line (also referred to as a second voltage line) VRL, and an initialization voltage line VIL.

The first transistor T1 may be a driving transistor, and the second to sixth transistors T2, T3, T4, T5, and T6 may be switching transistors. The first to sixth transistors T1, T2, T3, T4, T5, and T6 may be implemented as thin-film transistors. Depending on the type (P-type or N-type) and/or an operation condition of a transistor, a first terminal of each of the first to sixth transistors T1, T2, T3, T4, T5, and T6 may be a source or a drain, and a second terminal thereof may be a terminal different from the first terminal. In an embodiment, in the case where the first terminal is a source, the second terminal may be a drain.

In an embodiment, at least one of the first to sixth transistors T1, T2, T3, T4, T5, and T6 may be an N-channel transistor. In an embodiment, at least the first transistor T1 may be an N-channel transistor. The pixel circuit PC shown in FIG. 4 is an embodiment in which, among the first to sixth transistors T1, T2, T3, T4, T5, and T6, the first transistor T1, the second transistor T2, the third transistor T3, and the fourth transistor T4 are N-channel transistors, and the fifth transistor T5 and the sixth transistor T6 are P-channel transistors.

An N-channel transistor may be an oxide thin-film transistor including an oxide semiconductor. A semiconductor of an oxide thin-film transistor may include an oxide of amorphous indium gallium-zinc-oxide (“IGZO”), zinc oxide (ZnO), titanium oxide (TiO), or the like. A gate-on voltage of a gate signal that turns on an N-channel transistor may be a high-level voltage (a first level voltage), and a gate-off voltage of a gate signal that turns off an N-channel transistor may be a low-level voltage (a second level voltage).

A P-channel transistor may be a silicon thin-film transistor including a silicon semiconductor. A semiconductor of a silicon thin-film transistor may include amorphous silicon, polycrystalline silicon, or the like. A gate-on voltage of a gate signal that turns on a P-channel transistor may be a low-level voltage (a second level voltage), and a gate-off voltage of a gate signal that turns off a P-channel transistor may be a high-level voltage (a first level voltage).

The first transistor T1 may be connected between the driving voltage line PL and the organic light-emitting element OLED. The first transistor T1 may be connected to the fifth transistor T5 and the sixth transistor T6. The first transistor T1 may include a first terminal connected to the driving voltage line PL through the fifth transistor T5, and a second terminal electrically connected to a pixel electrode of the organic light-emitting element OLED through the sixth transistor T6. The first transistor T1 may output a driving current to the organic light-emitting element OLED, wherein the driving current corresponds to a data signal DATA applied to a gate of the first transistor T1. Hereinafter, a node to which the gate of the first transistor T1 is connected may be defined as a first node N1. The first terminal of the first transistor T1 may be a drain, and the second terminal of the first transistor T1 may be a source. A first driving voltage ELVDD may be transmitted to the driving voltage line PL.

The second transistor T2 may be connected between the data line DL and the first node N1. The second transistor T2 may include a gate, a first terminal, and a second terminal, wherein the gate is connected to the first gate line GWL, the first terminal is connected to the data line DL, and the second terminal is connected to the first node N1. The second transistor T2 may be turned on or turned off according to a first gate signal GW transmitted through the first gate line GWL and when the second transistor T2 is turned on, the second transistor T2 may transmit a data signal DATA to the first node N1, wherein the data signal DATA is transmitted to the data line DL.

The third transistor T3 may be connected to the gate of the first transistor T1 and the reference voltage line VRL. The third transistor T3 includes a gate, a first terminal, and a second terminal, wherein the gate is connected to the second gate line GRL, the first terminal is connected to the first node N1, and the second terminal is connected to the reference voltage line VRL. The third transistor T3 may be turned on or turned off according to a second gate signal GR transmitted to the second gate line GRL, and when the third transistor T3 is turned on, the third transistor T3 may transmit the reference voltage VREF to the first node N1, wherein the reference voltage VREF is transmitted to the reference voltage line VRL.

The fourth transistor T4 may be connected to the organic light-emitting element OLED and the initialization voltage line VIL. The fourth transistor T4 includes a gate, a first terminal, and a second terminal, wherein the gate is connected to the third gate line GBL, the first terminal is connected to the organic light-emitting element OLED, and the second terminal is connected to the initialization voltage line VIL. The first terminal of the fourth transistor T4 may be connected to the pixel electrode of the organic light-emitting element OLED. The fourth transistor T4 may be turned on or turned off according to a third gate signal GB transmitted to the third gate line GBL, and when the fourth transistor T4 is turned on, the fourth transistor T4 may initialize the pixel electrode by transmitting the initialization voltage VINT to the organic light-emitting element OLED, wherein the initialization voltage VINT is transmitted to the initialization voltage line VIL.

The fifth transistor T5 may be connected to the driving voltage line PL and the first transistor T1. The fifth transistor T5 may include a gate, a first terminal, and a second terminal, wherein the gate is connected to the fourth gate line EML1, the first terminal is connected to the driving voltage line PL, and the second terminal is connected to the first terminal of the first transistor T1. The fifth transistor T5 may be turned on or turned off according to a fourth gate signal EM1 transmitted to the fourth gate line EML1.

The sixth transistor T6 may be connected between the first transistor T1 and the organic light-emitting element OLED, or connected between the first transistor T1 and the third voltage line VIL. The sixth transistor T6 may include a gate, a first terminal, and a second terminal, wherein the gate is connected to the fifth gate line EML2, the first terminal is connected to the second terminal of the first transistor T1, and the second terminal is connected to the organic light-emitting element. The second terminal of the sixth transistor T6 may be connected to the pixel electrode of the organic light-emitting element OLED. The sixth transistor T6 may be turned on or turned off according to a fifth gate signal EM2 transmitted to the fifth gate line EML2.

The first capacitor Cst may be connected to the gate of the first transistor T1 and the first terminal of the sixth transistor T6. A first electrode of the first capacitor Cst may be connected to the first node N1, and a second electrode of the first capacitor Cst may be connected to the first terminal of the sixth transistor T6.

The second capacitor Chold may be connected to the first terminal of the sixth transistor T6 and the driving voltage line PL. A first electrode of the second capacitor Chold may be connected to the first terminal of the sixth transistor T6, and a second electrode of the second capacitor Chold may be connected to the driving voltage line PL.

The first capacitor Cst and the second capacitor Chold may share a node (also referred to as a second node N2, hereinafter) connected to the first terminal of the sixth transistor T6.

The organic light-emitting element OLED may include the pixel electrode (e.g., an anode) and the opposite electrode (e.g., a cathode) facing the pixel electrode, wherein the opposite electrode may receive the second driving voltage ELVSS. The organic light-emitting element OLED may display images by receiving the driving current from the first transistor T1 and emitting light of a preset color, wherein the driving current corresponds to a data signal DATA.

Referring to FIG. 5, the pixel PX may perform initialization, compensation, and data writing during a non-emission period of a frame, and emit light during an emission period of a frame. A period during which a fourth gate signal EM1 and a fifth gate signal EM2 are gate-on voltages may be the emission period. A period during which at least one of a fourth gate signal EM1 and a fifth gate signal EM2 is a gate-off voltage may be the non-emission period. The non-emission period may include a first period P1, a second period P2, a third period P3, and a fourth period P4. Gate-on voltages of a fourth gate signal EM1 and a fifth gate signal EM2 may be determined depending on a channel type of a transistor to which a fourth gate signal EM1 and a fifth gate signal EM2 are supplied. In FIG. 5, the gate-on voltages of a fourth gate signal EM1 and a fifth gate signal EM2 may be second level voltages.

The first period P1 may be a first initialization period in which the first node N1 to which the gate of the first transistor T1 is connected is initialized. During the first period P1, a first gate signal GW of a second level voltage may be supplied to the first gate line GWL from the gate driving circuit 130, a second gate signal GR of a first level voltage may be supplied to the second gate line GRL, a third gate signal GB of a first level voltage may be supplied to the third gate line GBL, a fourth gate signal EM1 of a first level voltage may be supplied to the fourth gate line EML1, and a fifth gate signal EM2 of a second level voltage may be supplied to the fifth gate line EML2. The timing of applying the first level voltage of the second gate signal GR may be delayed compared to the timing of applying the first level voltage of the third gate signal GB.

The third transistor T3 may be turned on according to a second gate signal GR of a first level voltage, and the gate of the first transistor T1 may be initialized to the reference voltage VREF.

The fourth transistor T4 may be turned on according to a third gate signal GB of a first level voltage, and the sixth transistor T6 may be turned on according to a fifth gate signal EM2 of a second level voltage. Accordingly, the initialization voltage VINT may be transmitted to the second node N2 to which the second terminal of the first transistor T1 is connected.

The fifth transistor T5 may be turned off according to a fourth gate signal EM1 of a first level voltage, and a current path between the driving voltage line PL and the first terminal of the first transistor T1 may be blocked. The second transistor T2 may be turned off according to a first gate signal GW of a second level voltage, and a current path between the data line DL and the gate of the first transistor T1 may be blocked.

The second period P2 may be a compensation period in which a threshold voltage of the first transistor T1 is compensated. During the second period P2, a first gate signal GW of a second level voltage may be supplied to the first gate line GWL from the gate driving circuit 130, a second gate signal GR of a first level voltage may be supplied to the second gate line GRL, a third gate signal GB of a first level voltage may be supplied to the third gate line GBL, a fourth gate signal EM1 of a second level voltage may be supplied to the fourth gate line EML1, and a fifth gate signal EM2 of a first level voltage may be supplied to the fifth gate line EML2.

The gate of the first transistor T1 may be maintained at the reference voltage VREF by the second gate signal GR of the first level voltage. The sixth transistor T6 may be turned off according to a fifth gate signal EM2 of a first level voltage, and the fifth transistor T5 may be turned on according to a fourth gate signal EM1 of a second level voltage. Accordingly, because the first driving voltage ELVDD is supplied to the first terminal of the first transistor T1, the first transistor T1 is turned on, and when an electrical potential difference between the gate and the second terminal of the first transistor T1, that is, a gate-source voltage Vgs becomes a threshold voltage Vth of the first transistor T1, the first transistor T1 may be turned off. In this case, because the voltage of the second terminal of the first transistor T1 is a difference (VREF-Vth) between the reference voltage VREF and the threshold voltage Vth of the first transistor T1, and a voltage corresponding to the threshold voltage Vth of the first transistor T1 is stored in the first capacitor Cst, the threshold voltage Vth of the first transistor T1 may be compensated. Where VREF denotes the voltage amount of the reference voltage VREF, and Vth denotes the voltage amount of the threshold voltage Vth.

The third period P3 may be a write period (a data programming period/data writing period) during which a data signal is supplied to the pixel PX. During the third period P3, a data signal may be supplied to the gate of the first transistor T1. During the third period P3, a first gate signal GW of a first level voltage may be supplied to the first gate line GWL from the gate driving circuit 130, a second gate signal GR of a second level voltage may be supplied to the second gate line GRL, a third gate signal GB of a first level voltage may be supplied to the third gate line GBL, a fourth gate signal EM1 of a first level voltage may be supplied to the fourth gate line EML1, and a fifth gate signal EM2 of a first level voltage may be supplied to the fifth gate line EML2.

The third period P3 may be a period during which a data signal is supplied to the pixels PX disposed in two rows (pixel rows). In an embodiment, as shown in FIG. 5, during the third period P3, an n-th first gate signal GW[n] of a first level voltage may be sequentially supplied to a pixel in an n-th row, and an (n+1)-th first gate signal GW[n+1] of a first level voltage may be sequentially supplied to a pixel in an (n+1)-th row. An n-th first gate signal GW[n] of a first level voltage and an (n+1)-th first gate signal GW[n+1] of a first level voltage may partially overlap each other.

The fifth transistor T5 may be turned off according to a fourth gate signal EM1 of a first level voltage, and the third transistor T3 may be turned off according to a second gate signal GR of a second level voltage. Then, the second transistor T2 may be turned on according to a first gate signal GW of a first level voltage, and the second transistor T2 that is turned on may transfer a data signal DATA from the data line DL to the gate of the first transistor T1. A voltage of the first node N1 may be changed from the reference voltage VREF to a voltage Vdata corresponding to the data signal DATA. In this case, in response to the voltage change amount of the first node N1, the voltage of the second node N2 may become a voltage (VREF-Vth+α×(Vdata-VREF)) changed according to the capacity ratio (α=C1/(C1+C2)) of the first capacitor Cst and the second capacitor Chold. The first capacitor Cst may be charged with the threshold voltage Vth of the first transistor T1 and the voltage Vdata corresponding to the data signal DATA. Where C1 denotes the capacity amount of first capacitor Cst, and C2 denotes the capacity amount of the second capacitor Chold.

The fourth period P4 may be a second initialization period of initializing the pixel electrode of the organic light-emitting element OLED before the emission period after data writing period. During the fourth period P4, a first gate signal GW of a second level voltage may be supplied to the first gate line GWL from the gate driving circuit 130, a second gate signal GR of a second level voltage may be supplied to the second gate line GRL, a third gate signal GB of a first level voltage may be supplied to the third gate line GBL, a fourth gate signal EM1 of a first level voltage may be supplied to the fourth gate line EML1, and a fifth gate signal EM2 of a second level voltage may be supplied to the fifth gate line EML2.

The fourth transistor T4 may be turned on according to a third gate signal GB of a first level voltage, and the sixth transistor T6 may be turned on according to a fifth gate signal EM2 of a second level voltage. Accordingly, the initialization voltage VINT may be transmitted to the second node N2 to which the second terminal of the first transistor T1 is connected, and the pixel electrode of the organic light-emitting element OLED. The electrical potential of the gate-source voltage Vgs of the first transistor T1 may be maintained by the first capacitor Cst.

The fifth period P5 may be a period in which the organic light-emitting element OLED emits light. During the fifth period P5, a first gate signal GW of a second level voltage may be supplied to the first gate line GWL from the gate driving circuit 130, a second gate signal GR of a second level voltage may be supplied to the second gate line GRL, a third gate signal GB of a second level voltage may be supplied to the third gate line GBL, a fourth gate signal EM1 of a second level voltage may be supplied to the fourth gate line EML1, and a fifth gate signal EM2 of a second level voltage may be supplied to the fifth gate line EML2.

The fourth transistor T4 may be turned off according to a third gate signal GB of a second level voltage, and the fifth transistor T5 may be turned on according to a fourth gate signal EM1 of a second level voltage. The first driving voltage ELVDD may be supplied to the first terminal of the first transistor T1 by the fifth transistor T5. The first transistor T1 may output a driving current (Id∝(Vgs-Vth)²) having a value corresponding to a voltage (Vgs-Vth) obtained by subtracting the threshold voltage Vth of the first transistor T1 from the gate-source voltage Vgs of the first transistor T1. The driving current may flow through the organic light-emitting element OLED through the sixth transistor T6 that is turned on according to a fifth gate signal EM2 of a second level voltage, and the organic light-emitting element OLED may emit light at a brightness corresponding to the driving current.

As described with reference to FIG. 5, before the third period P3, the gate-source voltage Vgs of the first transistor T1 is the threshold voltage Vth of the first transistor T1. During the third period P3, when a data signal DATA other than black is written, the gate-source voltage of the first transistor T1 becomes a value greater than the threshold voltage Vth of the first transistor T1 and thus the first transistor T1 is turned on, charge is supplied from the first terminal of the first transistor T1 to the second terminal of the first transistor T1, and the voltage of the second terminal of the first transistor T1 and the voltage of the second node N2 may be changed.

As shown in FIG. 6, an example is assumed in which, during the third period P3, a first gate signal GW is supplied to a first pixel in an (n-1)-th row and a second pixel in an n-th row of the same column as the first pixel. First gate signals GW output to pixel rows may partially overlap each other. While an (n-1)-th first gate signal GW[n-1] of a first level voltage is supplied, data signals of WHITE/GRAY/GRAY/GRAY may be sequentially supplied to the first pixel, and while an n-th first gate signal GW[n] of a first level voltage is supplied, data signals of GRAY/GRAY/GRAY/GRAY may be sequentially supplied to the second pixel. Where WHITE denotes a white scale level of the data signal DATA, and GRAY denotes a gray scale level of the data signal DATA.

In the case of the first pixel, when a data signal DATA of WHITE is written, the gate-source voltage Vgs of the first transistor T1 becomes a difference (Vg(WHITE)-(VREF-Vth+α×(Vdata(WHITE)-VREF)) between the gate voltage Vg(WHITE) of the first transistor T1 and the voltage of the second terminal (VREF-Vth+α×(Vdata(WHITE)-VREF)), so that the first transistor T1 is turned on and the voltage of the second terminal of the first transistor T1 may be changed. Then, the data signal DATA is changed to GRAY, and the gate-source voltage Vgs of the first transistor T1 may become (Vg(GRAY)-(VREF-Vth+α ×(Vdata(GRAY)-VREF)+△V). △V is the voltage change amount of the second terminal of the first transistor T1 of the first pixel (or the second node N2 of the first pixel). Where Vg(WHITE) denotes a voltage of the gate of the first transistor T1 and Vdata(WHITE) denotes a voltage corresponding the data signal DATA, when the data signal DATA of WHITE is written. Where Vg(GRAY) denotes a voltage of the gate of the first transistor T1 and Vdata(GRAY) denotes a voltage corresponding the data signal DATA, when the data signal DATA of GRAY is written.

In the case of the second pixel, when a data signal DATA of GRAY is written, the gate-source voltage Vgs of the first transistor T1 becomes a difference (Vg(GRAY)-(VREF-Vth+α×(Vdata(GRAY)-VREF)) between the gate voltage Vg(GRAY) of the first transistor T1 and the voltage of the second terminal (VREF-Vth+α×(Vdata(GRAY)-VREF)), so that the first transistor T1 is turned on and the voltage of the second terminal of the first transistor T1 may be changed. Then, the data signal DATA of second GRAY is written, and the gate-source voltage Vgs of the first transistor T1 may become (Vg(GRAY)-(VREF-Vth+α ×(Vdata(GRAY)-VREF)+△V'). △V' is the voltage change amount of the second terminal of the first transistor T1 of the second pixel, and is different from the voltage change amount △V of the second terminal of the first transistor T1 of the first pixel.

A final data signal DATA written to the first pixel and a final data signal DATA written to the second pixel are both the same in GRAY. However, data signals DATA of WHITE/GRAY/GRAY/GRAY written to the first pixel and data signals DATA of GRAY/GRAY/GRAY/GRAY written to the second pixel are different from each other. Accordingly, a final value of the voltage change amount △V of the second terminal of the first transistor T1 of the first pixel, and a final value of the voltage change amount △V' of the second terminal of the first transistor T1 of the second pixel may be different from each other. Depending on the previous data signal, the voltage changes of the second terminal of the first transistor T1 (or the second node N2) of the first pixel and the second pixel are different from each other, and accordingly, a brightness difference may occur between the first pixel and the second pixel to which the data signal DATA of the same GRAY is finally written.

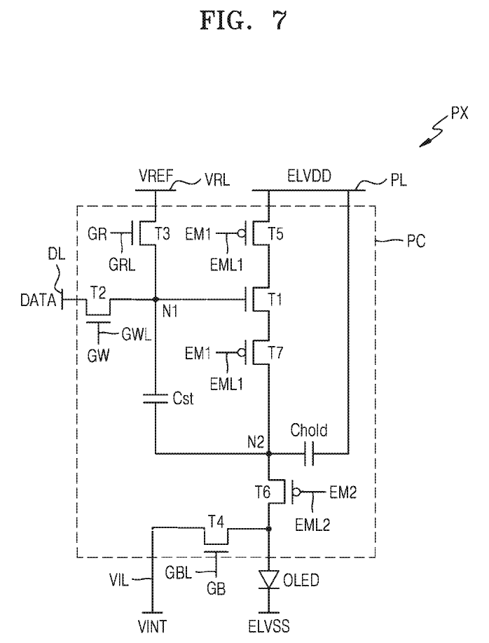

FIG. 7 is a schematic equivalent circuit diagram of an embodiment of the pixel PX.

The pixel PX shown in FIG. 7 is different from the pixel PX shown in FIG. 4 in that the seventh transistor T7 is added. An operation of the pixel PX shown in FIG. 7 is described with reference to FIG. 5. Hereinafter, the differences in the construction and operation of the pixel PX shown in FIG. 7 are mainly described.

The seventh transistor T7 may be a P-channel transistor. The seventh transistor T7 may be a switching transistor. The seventh transistor T7 may be connected to the first transistor T1 and the sixth transistor T6. The seventh transistor T7 may include a gate, a first terminal, and a second terminal, wherein the gate is connected to the fourth gate line EML1, the first terminal is connected to the second terminal of the first transistor T1, and the second terminal is connected to the first terminal of the sixth transistor T6. The seventh transistor T7 may be turned on or turned off according to a fourth gate signal EM1 transferred to the fourth gate line EML1. The fifth transistor T5 and the seventh transistor T7 may be simultaneously turned on.

During the first period P1, the third transistor T3 may be turned on according to a second gate signal GR of a first level voltage, and the gate of the first transistor T1 may be initialized to the reference voltage VREF. The fourth transistor T4 may be turned on according to a third gate signal GB of a first level voltage, and the sixth transistor T6 may be turned on according to a fifth gate signal EM2 of a second level voltage. Accordingly, the initialization voltage VINT may be transferred to the second node N2.

The fifth transistor T5 and the seventh transistor T7 are turned off according to a fourth gate signal EM1 of a first level voltage, a current path between the driving voltage line PL and the first terminal of the first transistor T1 and a current path between the second terminal of the first transistor T1 and the second node N2 are blocked, and the first transistor T1 may be turned off.

During the second period P2, the gate of the first transistor T1 may be maintained at the reference voltage VREF by the second gate signal GR of the first level voltage. The sixth transistor T6 may be turned off according to a fifth gate signal EM2 of a first level voltage, and the fifth transistor T5 and the seventh transistor T7 may be turned on according to a fourth gate signal EM1 of a second level voltage. The first transistor T1 may be turned on according to the fifth transistor T5 and the seventh transistor T7 that are turned on, and when the gate-source voltage Vgs of the first transistor T1 becomes the threshold voltage Vth of the first transistor T1, the first transistor T1 may be turned off. In this case, because the voltage of the second terminal of the first transistor T1 and the voltage of the second node N2 is a difference (VREF-Vth) between the reference voltage VREF and the threshold voltage Vth of the first transistor T1, and a voltage corresponding to the threshold voltage Vth of the first transistor T1 is stored in the first capacitor Cst, the threshold voltage Vth of the first transistor T1 may be compensated.

During the third period P3, the second transistor T2 may be turned on according to a first gate signal GW of a first level voltage, and the second transistor T2 that is turned on may transmit a data signal DATA from the data line DL to the gate of the first transistor T1. In response to the voltage change amount of the first node N1, the voltage of the second node N2 may be a voltage (VREF-Vth+α×(Vdata-VREF)) changed according to the capacity ratio (α=C1/(C1+C2)) of the first capacitor Cst and the second capacitor Chold. The first capacitor Cst may be charged with the threshold voltage Vth of the first transistor T1 and the voltage Vdata corresponding to the data signal DATA.

The fifth transistor T5 and the seventh transistor T7 are turned off according to a fourth gate signal EM1 of a first level voltage, and a current path between the second terminal of the first transistor T1 and the second node N2 may be blocked. Accordingly, a voltage change of the second node N2 may be reduced, and a brightness deviation between pixels to which the same data signal DATA is written may be reduced.

During the fourth period P4, the fourth transistor T4 may be turned on according to a third gate signal GB of a first level voltage, and the sixth transistor T6 may be turned on according to a fifth gate signal EM2 of a second level voltage. Accordingly, the initialization voltage VINT may be transferred to the second node N2 and the pixel electrode of the organic light-emitting element OLED. Because the fifth transistor T5 and the seventh transistor T7 are turned off according to a fourth gate signal EM1 of a first level voltage, a current path between the second terminal of the first transistor T1 and the second node N2 may be blocked.

During the fifth period P5, through the fifth transistor T5 and the seventh transistor T7 that are turned on according to a fourth gate signal EM1 of a second level voltage, and the sixth transistor T6 that is turned on according to a fifth gate signal EM2 of a second level voltage, the driving current (Id ∝ (Vgs-Vth)²) output by the first transistor T1 may flow through the organic light-emitting element OLED, and the organic light-emitting element OLED may emit light at a brightness corresponding to the driving current.

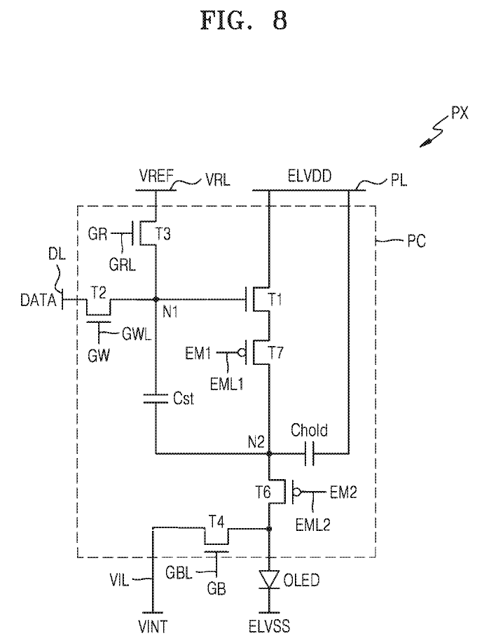

FIG. 8 is a schematic equivalent circuit diagram of an embodiment of the pixel PX.

The pixel PX shown in FIG. 8 is different from the pixel shown in FIG. 4 in that the fifth transistor T5 is omitted and the seventh transistor T7 is added. An operation of the pixel PX shown in FIG. 8 is described with reference to FIG. 5. Hereinafter, the differences in the construction and operation of the pixel PX shown in FIG. 8 are mainly described.

The seventh transistor T7 may be a P-channel transistor. The seventh transistor T7 may be a switching transistor. The seventh transistor T7 may be connected to the first transistor T1 and the sixth transistor T6. The seventh transistor T7 may include a gate, a first terminal, and a second terminal, wherein the gate is connected to the fourth gate line EML1, the first terminal is connected to the second terminal of the first transistor T1, and the second terminal is connected to the first terminal of the sixth transistor T6. The seventh transistor T7 may be turned on or turned off according to a fourth gate signal EM1 transmitted to the fourth gate line EML1.

During the first period P1, the third transistor T3 may be turned on according to a second gate signal GR of a first level voltage, and the gate of the first transistor T1 may be initialized to the reference voltage VREF. The fourth transistor T4 may be turned on according to a third gate signal GB of a first level voltage, and the sixth transistor T6 may be turned on according to a fifth gate signal EM2 of a second level voltage. Accordingly, the initialization voltage VINT may be transmitted to the second node N2.

Because the first driving voltage ELVDD is supplied to the first terminal of the first transistor T1, the first transistor T1 is turned on, and when an electrical potential difference between the gate and the second terminal of the first transistor T1, that is, a gate-source voltage Vgs becomes a threshold voltage Vth of the first transistor T1, the first transistor T1 may be turned off. In this case, the voltage of the second terminal of the first transistor T1 may be a difference (VREF-Vth) between the reference voltage VREF and the threshold voltage Vth of the first transistor T1. In this case, because the seventh transistor T7 is turned off according to a fourth gate signal EM1 of a first level voltage, a current path between the second terminal of the first transistor T1 and the second node N2 may be blocked.

During the second period P2, the gate of the first transistor T1 may be maintained at the reference voltage VREF by the second gate signal GR of the first level voltage. The sixth transistor T6 may be turned off according to a fifth gate signal EM2 of a first level voltage, and the seventh transistor T7 may be turned on according to a fourth gate signal EM1 of a second level voltage. Because the voltage of the second node N2 becomes a difference (VREF-Vth) between the reference voltage VREF, which is the voltage of the second terminal of the first transistor T1, and the threshold voltage Vth of the first transistor T1, and a voltage corresponding to the threshold voltage Vth of the first transistor T1 is stored in the first capacitor Cst, the threshold voltage Vth of the first transistor T1 may be compensated.

During the third period P3, the third transistor T3 may be turned off according to a second gate signal GR of a second level voltage, the second transistor T2 is turned on according to a first gate signal GW of a first level voltage, and a voltage Vdata corresponding to a data signal DATA may be transmitted to the gate of the first transistor T1 by the second transistor T2 that is turned on. In response to the voltage change amount of the first node N1, the voltage of the second node N2 may be a voltage (VREF-Vth+α×(Vdata-VREF)) changed according to the capacity ratio (α=C1/(C1+C2)) of the first capacitor Cst and the second capacitor Chold. The first capacitor Cst may be charged with the threshold voltage Vth of the first transistor T1 and the voltage Vdata corresponding to the data signal DATA.

Because the seventh transistor T7 is turned off according to a fourth gate signal EM1 of a first level voltage, a current path between the second terminal of the first transistor T1 and the second node N2 may be blocked. Accordingly, a voltage change of the second node N2 may be reduced, and a brightness deviation between pixels to which the same data signal DATA is written may be reduced.

During the fourth period P4, the fourth transistor T4 may be turned on according to a third gate signal GB of a first level voltage, and the sixth transistor T6 may be turned on according to a fifth gate signal EM2 of a second level voltage. Accordingly, the initialization voltage VINT may be transmitted to the second node N2 and the pixel electrode of the organic light-emitting element OLED. Because the seventh transistor T7 is turned off according to a fourth gate signal EM1 of a first level voltage, a current path between the second terminal of the first transistor T1 and the second node N2 may be blocked.

During the fifth period P5, through the seventh transistor T7 that are turned on according to a fourth gate signal EM1 of a second level voltage, and the sixth transistor T6 that is turned on according to a fifth gate signal EM2 of a second level voltage, the driving current (Id ∝ (Vgs-Vth)²) output by the first transistor T1 may flow through the organic light-emitting element OLED, and the organic light-emitting element OLED may emit light at a brightness corresponding to the driving current.

FIG. 9 is a schematic equivalent circuit diagram of an embodiment of the pixel PX.

The pixel PX shown in FIG. 9 is different from the pixel shown in FIG. 4 in that the fifth transistor T5 is omitted and the seventh transistor T7 and the eighth transistor T8 are added. An operation of the pixel PX shown in FIG. 9 is described with reference to FIG. 5. Because the pixel PX shown in FIG. 9 is different from the pixel PX shown in FIG. 7 in that the eighth transistor T8 is added, the differences in the construction and operation of the pixel PX shown in FIG. 9 are mainly described below.

The eighth transistor T8 may be an N-channel transistor. The eighth transistor T8 may be a switching transistor. The eighth transistor T8 may be connected to the first transistor T1 and the driving voltage line PL. The eighth transistor T8 may include a gate, a first terminal, and a second terminal, wherein the gate is connected to the first gate line GWL, the first terminal is connected to the second terminal of the first transistor T1, and the second terminal is connected to the driving voltage line PL. The eighth transistor T8 may be turned on according to a first gate signal GW to transmit the first driving voltage ELVDD to a third node N3, wherein the first gate signal GW is transmitted to the first gate line GWL. The third node N3 may be a node to which the second terminal of the first transistor T1 and the first terminal of the seventh transistor T7 are connected. The eighth transistor T8 may be a control element configured to control the voltage of the second terminal of the first transistor T1 by transmitting the first driving voltage ELVDD to the second terminal of the first transistor T1.

During the first period P1 and the second period P2, the eighth transistor T8 may be turned off according to a first gate signal GW of a second level voltage.

During the third period P3, the third transistor T3 may be turned off according to a second gate signal GR of a second level voltage, and the second transistor T2 may be turned on according to a first gate signal GW of a first level voltage. A voltage Vdata corresponding to a data signal may be transmitted to the gate of the first transistor T1 via the second transistor T2 that is turned on. In response to the voltage change amount of the first node N1, the voltage of the second node N2 may be a voltage (VREF-Vth+α×(Vdata-VREF)) changed according to the capacity ratio (α=C1/(C1+C2)) of the first capacitor Cst and the second capacitor Chold. The first capacitor Cst may be charged with the threshold voltage Vth of the first transistor T1 and the voltage Vdata corresponding to the data signal DATA.

The seventh transistor T7 may be turned off according to a fourth gate signal EM1 of a first level voltage, and the eighth transistor T8 may be turned on according to a first gate signal GW of a first level voltage. A current path between the second terminal of the first transistor T1 and the second node N2 may be blocked by the seventh transistor T7, and the first driving voltage ELVDD may be transmitted to the third node N3 by the eighth transistor T8.

Because the second terminal of the first transistor T1 and the second node N2 are separated from each other by the seventh transistor T7, during the third period P3, a change in a data signal does not directly influence the gate-source voltage Vgs of the first transistor T1, but a parasitic capacitor due to the second terminal of the first transistor T1 may be formed at the third node N3. The gate-source voltage Vgs of the first transistor T1 may be influenced by a voltage deviation stored in the parasitic capacitor formed in the second terminal of the first transistor T1 of the pixels PX, a voltage deviation of the second node N2 may occur, and a brightness deviation may occur between pixels PX to which the same data signal DATA is supplied.

Because the second terminal of the first transistor T1 is initialized to the first driving voltage ELVDD by the eighth transistor T8, a voltage change in the second terminal of the first transistor T1 and a voltage change in the second node N2 may be reduced, and thus, a brightness deviation between pixels PX to which the same data signal DATA is supplied may be reduced.

During the fourth period P4, the fourth transistor T4 may be turned on according to a third gate signal GB of a first level voltage, and the sixth transistor T6 may be turned on according to a fifth gate signal EM2 of a second level voltage. Accordingly, the initialization voltage VINT may be transmitted to the second node N2 and the pixel electrode of the organic light-emitting element OLED.

During the fifth period P5, through the seventh transistor T7 that are turned on according to a fourth gate signal EM1 of a second level voltage, and the sixth transistor T6 that is turned on according to a fifth gate signal EM2 of a second level voltage, the driving current (Id ∝ (Vgs-Vth)²) output by the first transistor T1 may flow through the organic light-emitting element OLED, and the organic light-emitting element OLED may emit light at a brightness corresponding to the driving current.

During the fourth period P4 and the fifth period P5, the eighth transistor T8 may be turned off according to a first gate signal GW of a second level voltage.

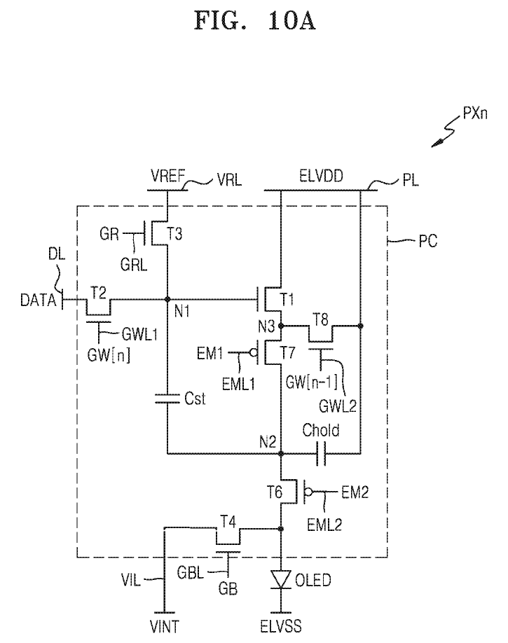

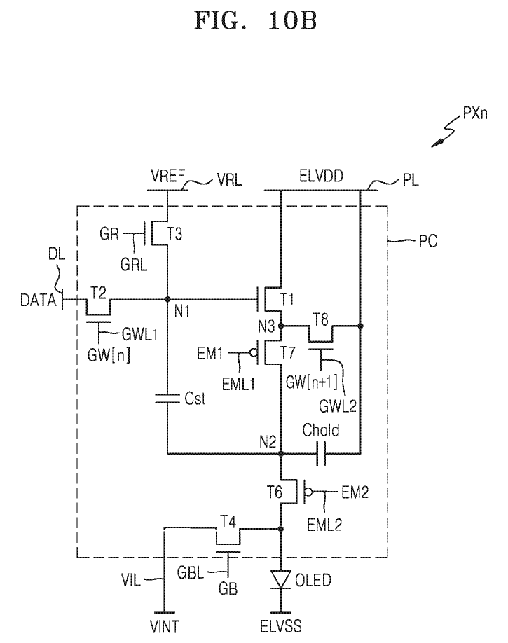

FIGS. 10A and 10B are schematic equivalent circuit diagrams of an embodiment of the pixel PXn.

As shown in FIG. 9, in the pixel PX, a first gate signal GW supplied to the gate of the second transistor T2 and a first gate signal GW supplied to the gate of the eighth transistor T8 may be the same to each other. In another embodiment, a first gate signal GW supplied to the gate of the eighth transistor T8 may be a first gate signal GW (also referred to as a previous first gate signal) shifted forward in time or a first gate signal GW (also referred to as a next first gate signal) shifted backward in time compared to a first gate signal GW supplied to the gate of the second transistor T2. Waveforms of a first gate signal GW supplied to the gate of the eighth transistor T8, a previous first gate signal, and a next first gate signal may be the same to each other.

A previous first gate signal may be a first gate signal GW supplied to the gate of the second transistor T2 in at least one previous row. A next first gate signal may be a first gate signal GW supplied to the gate of the second transistor T2 in at least one next row. A period during which a previous first gate signal and a next first gate signal supplied to the gate of the eighth transistor T8 are gate-on voltages may overlap at least a portion of a period from after the second period P2 (or after the third period P3) to before the fifth period P5.

In an embodiment, as shown in FIG. 10A, the gate of the eighth transistor T8 may be connected to a first gate line GWL2, and a gate signal supplied to the gate of the eighth transistor T8 may be a previous first gate signal GW[n-1]. In an embodiment, when a pixel PXn shown in FIG. 10A is a pixel in an n-the row, an n-th first gate signal GW[n] may be supplied to the gate of the second transistor T2, and an (n-1)-th first gate signal GW[n-1] may be supplied to the gate of the eighth transistor T8. An (n-1)-th first gate signal GW[n-1] may be a gate signal supplied to the gate of the second transistor T2 of a pixel in an (n-1)-th row. The sixth gate line GWL2 connected to a pixel PXn in an n-th row may be connected to a first gate line GWL1 connected to the gate of the second transistor T2 of a pixel in an (n-1)-th row.

In an embodiment, as shown in FIG. 10B, a gate signal supplied to the gate of the eighth transistor T8 may be a next (n+1)-th first gate signal GW[n+1]. In an embodiment, when a pixel PXn shown in FIG. 10B is a pixel in an n-the row, an n-th first gate signal GW[n] may be supplied to the gate of the second transistor T2, and an (n+1)-th first gate signal GW[n+1] may be supplied to the gate of the eighth transistor T8. An (n+1)-th first gate signal GW[n+1] may be a gate signal supplied to the gate of the second transistor T2 of a pixel in an (n+1)-th row. The first gate line GWL2 connected to a pixel PXn in an n-th row may be connected to a first gate line GWL1 connected to the gate of the second transistor T2 of a pixel in an (n+1)-th row.

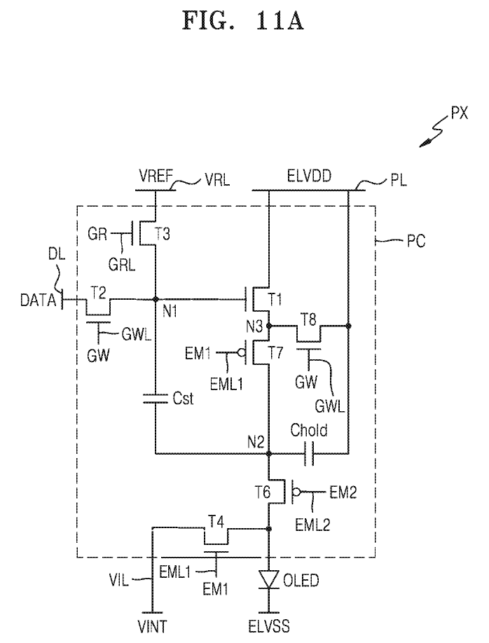

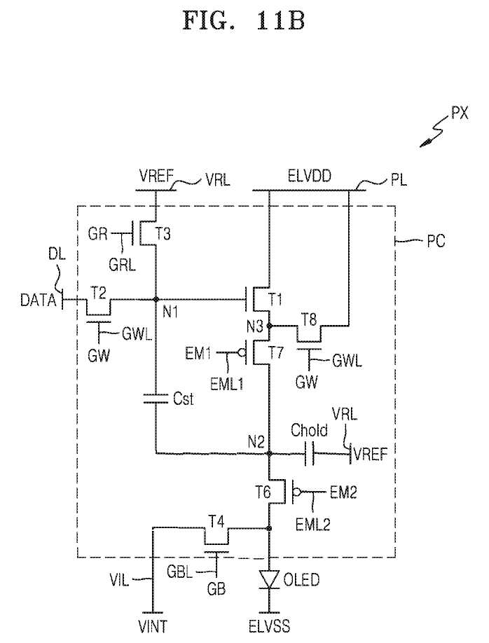

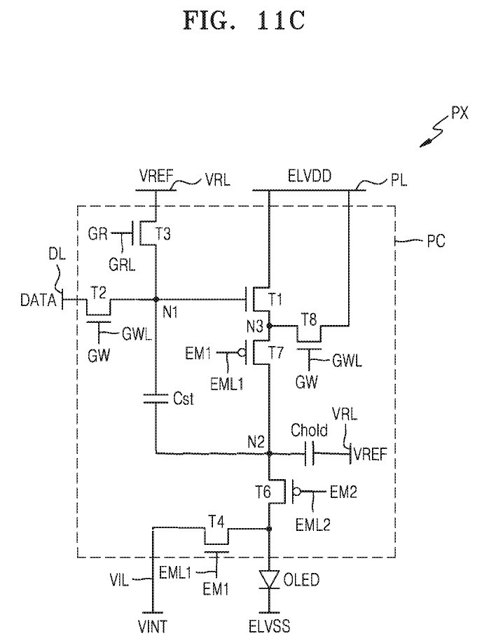

FIGS. 11A to 11C are schematic equivalent circuit diagrams of an embodiment of a pixel PX. The pixels PX shown in FIGS. 11A to 11C are modified embodiments of the pixel PX shown in FIG. 9. Hereinafter, differences are mainly described.

The pixel PX shown in FIG. 11A is different from the pixel PX shown in FIG. 9 in that the gate of the fourth transistor T4 is connected to the fourth gate line EML1. The gate of the fourth transistor T4 may receive a fourth gate signal EM1 from the fourth gate line EML1. Because, in the display device to which the pixel PX shown in FIG. 11A is applied, the third driving circuit 135 (refer to FIG. 2) may be omitted, the size of the peripheral area PA may be reduced.

During the fourth period P4, the fourth transistor T4 is turned on according to a fourth gate signal EM1 of a first level voltage, and the initialization voltage VINT may be transmitted to the second node N2 and the pixel electrode of the organic light-emitting element OLED.

The second capacitor Chold may be connected to the voltage source configured to supply a constant voltage to the second node N2. The constant voltage may be the first driving voltage ELVDD, the reference voltage VREF, the initialization voltage VINT, or the second driving voltage ELVSS. In an embodiment, as shown in FIG. 9, the second capacitor Chold may be connected to the second node N2 and a voltage source (e.g., the driving voltage line PL or a first driving voltage ELVDD supplying line in the peripheral area PA, or the like) supplying the first driving voltage ELVDD. In an alternative embodiment, as shown in FIG. 11B, the second capacitor Chold may be connected to the second node N2 and a voltage source (e.g., the reference voltage line VRL or a reference voltage VREF supplying line in the peripheral area PA, or the like) supplying the reference voltage VREF.

Although not shown, the second capacitor Chold may be connected to the second node N2 and a voltage source (e.g., the initialization voltage line VIL or an initialization voltage VINT supplying line in the peripheral area PA, or the like) supplying the initialization voltage VINT. In an alternative embodiment, the second capacitor Chold may be connected to the second node N2 and a voltage source (e.g., an opposite electrode or a second driving voltage ELVSS supplying line, or the like in the peripheral area PA) supplying the second driving voltage ELVSS.

The pixel PX shown in FIG. 11C is an embodiment in which the gate of the fourth transistor T4 is connected to the fourth gate line EML1, and the second capacitor Chold is connected to the second terminal of the seventh transistor T7 and the reference voltage line VRL. In an embodiment, a gate signal supplied to the gate of the the seventh transistor T7 and a gate signal supplied to the gate of the fourth transistor T4 may be the same to each other.

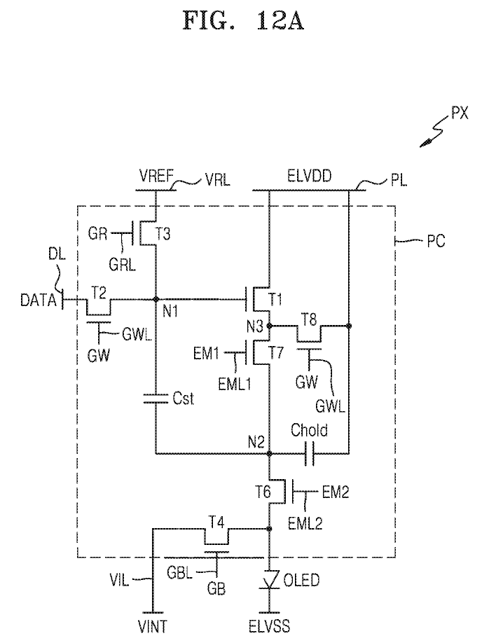

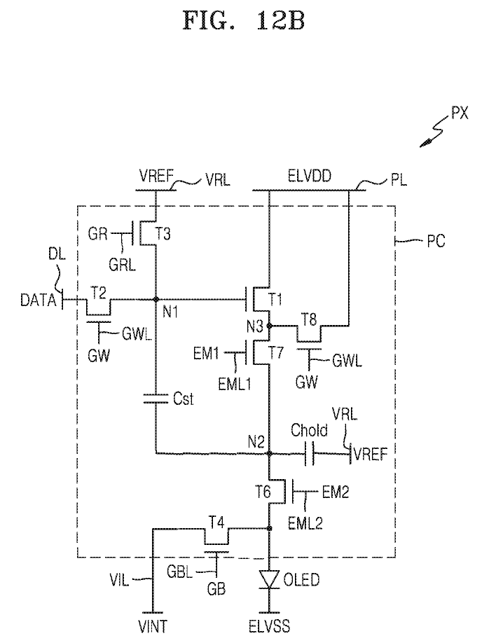

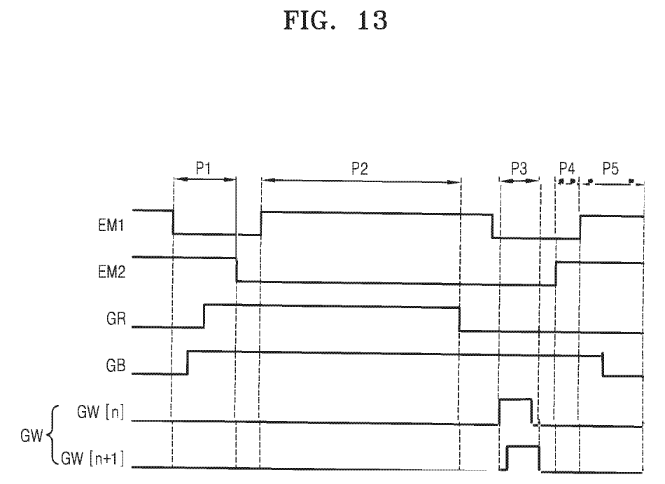

FIGS. 12A and 12B are schematic equivalent circuit diagrams of an embodiment of the pixel PX. FIG. 13 is a timing diagram to explain an operation of pixels PX shown in FIGS. 12A and 12B. The pixels PX shown in FIGS. 12A and 12B are modified embodiments of the pixel PX shown in FIG. 9.

The pixel PX shown in FIG. 12A is different from the pixel PX shown in FIG. 9 in that the sixth transistor T6 and the seventh transistor T7 are N-channel transistors.

The pixel PX shown in FIG. 12B is different from the pixel PX shown in FIG. 9 in that the second capacitor Chold is connected to the second terminal of the seventh transistor T7 and the reference voltage line VRL, and the sixth transistor T6 and the seventh transistor T7 are N-channel transistors.

Because, in the pixels PX shown in FIGS. 12A and 12B, the sixth transistor T6 and the seventh transistor T7 are N-channel transistors, as shown in FIG. 13, the waveforms of a fourth gate signal EM1 and a fifth gate signal EM2 may be opposite to the waveforms of a fourth gate signal EM1 and a fifth gate signal EM2 shown in FIG. 5. The operations of the pixels PX shown in FIGS. 12A and 12B are the same as the operation of the pixel PX shown in FIG. 9 described with reference to FIG. 5. Hereinafter, differences are mainly described.

Referring to FIG. 13, during the first period P1, the gate driving circuit 130 may supply a fourth gate signal EM1 of a second level voltage to the fourth gate line EML1, and may supply a fifth gate signal EM2 of a first level voltage to the fifth gate line EML2.

During the second period P2, the gate driving circuit 130 may supply a fourth gate signal EM1 of a first level voltage to the fourth gate line EML1, and may supply a fifth gate signal EM2 of a second level voltage to the fifth gate line EML2.

During the third period P3, from the gate driving circuit 130 may supply a fourth gate signal EM1 of a second level voltage to the fourth gate line EML1, and may supply a fifth gate signal EM2 of a second level voltage to the fifth gate line EMLb.

During the fourth period P4, from the gate driving circuit 130 may supply a fourth gate signal EM1 of a second level voltage to the fourth gate line EML1, and may supply a fifth gate signal EM2 of a first level voltage to the fifth gate line EML2.

During the fifth period P5, from the gate driving circuit 130 may supply a fourth gate signal EM1 of a first level voltage to the fourth gate line EML1, and may supply a fifth gate signal EM2 of a first level voltage to the fifth gate line EML2.

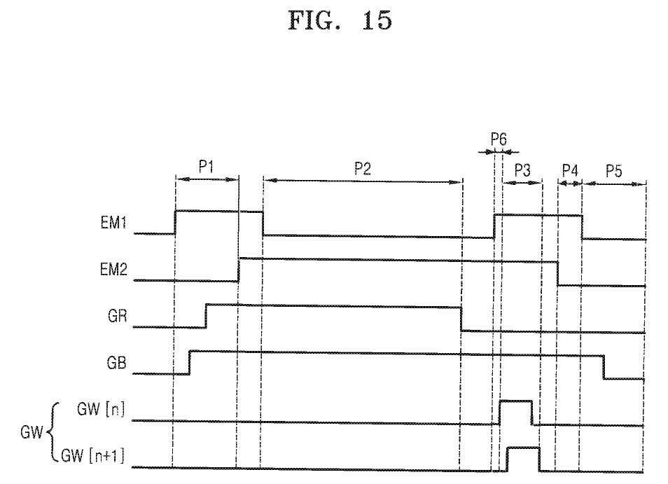

FIG. 14 is a schematic equivalent circuit diagram of an embodiment of a pixel PX. FIG. 15 is a timing diagram to explain an operation of the pixel PX shown in FIG. 14.

The pixel PX shown in FIG. 14 is different from the pixel PX shown in FIG. 8 in that a third capacitor Cboost is further included. A timing diagram shown in FIG. 15 is different from a timing diagram shown in FIG. 5 in that a sixth period P6 is added. Hereinafter, differences are mainly described.

The third capacitor Cboost may be connected to the first transistor T1 and the seventh transistor T7. A first electrode of the third capacitor Cboost may be connected to the third node N3 to which the second terminal of the first transistor T1 is connected, and a second electrode of the third capacitor Cboost may be connected to the fourth gate line EML1 to which the gate of the seventh transistor T7 is connected. The third capacitor Cboost may be a control element connected to the second terminal of the first transistor T1 and controlling the voltage of the second terminal of the first transistor T1.

Referring to FIG. 15, during the first period P1, the third transistor T3 may be turned on according to a second gate signal GR of a first level voltage, and the gate of the first transistor T1 may be initialized to the reference voltage VREF. The initialization voltage VINT may be transmitted to the second node N2 by the fourth transistor T4 that is turned on according to a third gate signal GB of a first level voltage and the sixth transistor T6 that is turned on according to a fifth gate signal EM2 of a second level voltage.

The first driving voltage ELVDD is supplied to the first terminal of the first transistor T1, the first transistor T1 is turned on, and when the voltage of the second terminal of the first transistor T1 is a difference (VREF-Vth) between the reference voltage VREF and the threshold voltage Vth of the first transistor T1, the first transistor T1 may be turned off. In this case, because the seventh transistor T7 is turned off according to a fourth gate signal EM1 of a first level voltage, a current path between the second terminal of the first transistor T1 and the second node N2 may be blocked.

During the second period P2, the gate of the first transistor T1 may be maintained at the reference voltage VREF by the second gate signal GR of the first level voltage. The sixth transistor T6 may be turned off according to a fifth gate signal EM2 of a first level voltage, and the seventh transistor T7 may be turned on according to a fourth gate signal EM1 of a second level voltage. The voltage of the second node N2 becomes a difference (VREF-Vth) between the reference voltage VREF, which is the voltage of the second terminal of the first transistor T1, and the threshold voltage Vth of the first transistor T1, and a voltage corresponding to the threshold voltage Vth of the first transistor T1 is stored in the first capacitor Cst, the threshold voltage Vth of the first transistor T1 may be compensated.

During the sixth period P6, a first gate signal GW of a second level voltage may be supplied to the first gate line GWL from the gate driving circuit 130, a second gate signal GR of a second level voltage may be supplied to the second gate line GRL, a third gate signal GB of a first level voltage may be supplied to the third gate line GBL, a fourth gate signal EM1 of a first level voltage may be supplied to the fourth gate line EML1, and a fifth gate signal EM2 of a first level voltage may be supplied to the fifth gate line EML2.

The second transistor T2 is turned off according to a first gate signal GW of a second level voltage, and the third transistor T3 is turned off according to a second gate signal GR of a second level voltage, the gate of the first transistor T1 may be maintained at the reference voltage VREF.

The sixth transistor T6 may be turned off according to a fifth gate signal EM2 of a first level voltage, and the seventh transistor T7 may be turned off according to a fourth gate signal EM1 of a first level voltage. Accordingly, the voltage of the second node N2 maintains the difference (VREF-Vth) between the reference voltage VREF and the threshold voltage Vth of the first transistor T1, and due to coupling of the third capacitor Cboost, the voltage of the second terminal of the first transistor T1 may change according to a voltage change amount (VGH-VGL) of a fourth gate signal EM1 and a capacitance ratio (C3/C4) of the third capacitor Cboost and a parasitic capacitor Csource formed at the second terminal of the first transistor T1. Here, the high level voltage VGH may be a first level voltage of a fourth gate signal EM1, and the low level voltage VGL may be a second level voltage of a fourth gate signal EM1. Where CboostC3 denotes the capacity amount of the third capacitor Cboost, and CsourceC4 denotes the capacity amount of the parasitic capacitor Csource.

The voltage of the second terminal of the first transistor T1 may be (VREF-Vth+(C3/C4)×(VGH-VGL)), and the gate-source voltage Vgs of the first transistor T1 may be the difference (VREF-Vth+(C3/C4)×(VGH-VGL)) (Vgs=(C3/C4)×(VGL-VGH)+Vth) between the reference voltage VREF and the voltage (VREF-Vth+(C3/C4)×(VGH-VGL)) of the second terminal of the first transistor T1. A gate-drain voltage Vgd of the first transistor T1 may be the difference (VREF-ELVDD) between the reference voltage VREF and the first driving voltage ELVDD of the first terminal of the first transistor T1. Because the gate-source voltage Vgs of the first transistor T1 and the gate-drain voltage Vgd of the first transistor T1 are values less than 0, the first transistor T1 may be turned off.

During the third period P3, the third transistor T3 may be turned off according to a second gate signal GR of a second level voltage, the second transistor T2 is turned on according to a first gate signal GW of a first level voltage, and a voltage Vdata corresponding to a data signal DATA may be transmitted to the gate of the first transistor T1 via the second transistor T2 that is turned on. In response to the voltage change amount of the first node N1, the voltage of the second node N2 may become a voltage (VREF-Vth+α×(Vdata-VREF)) changed according to the capacity ratio (α=C1/(C1+C2)) of the first capacitor Cst and the second capacitor Chold. The first capacitor Cst may be charged with the threshold voltage Vth of the first transistor T1 and the voltage Vdata corresponding to the data signal DATA.

Because the seventh transistor T7 is kept turned off by a fourth gate signal EM1 of the first level voltage, the voltage of the second terminal of the first transistor T1 may be maintained at the voltage (VREF-Vth+(Cboost/Csource)×(VGH-VGL)) of the second terminal of the first transistor T1 during the second period P2.

The gate-source voltage Vgs of the first transistor T1 may be a difference (Vgs= (C3/C4)×(VGL-VGH)+Vth) between the voltage (VREF) of the gate of the first transistor T1 and the voltage (VREF-Vth+(C3/C4)×(VGH-VGL)) of the second terminal of the first transistor T1. The gate-drain voltage Vgd of the first transistor T1 may be the difference (Vdata-ELVDD) between the voltage Vdata corresponding to the data signal DATA and a voltage of the first terminal of the first transistor T1 (i.e., the first driving voltage ELVDD). Because the gate-source voltage Vgs of the first transistor T1 and the gate-drain voltage Vgd of the first transistor T1 are values less than 0, the first transistor T1 may be turned off.

During the fourth period P4, the fourth transistor T4 may be turned on according to a third gate signal GB of a first level voltage, and the sixth transistor T6 may be turned on according to a fifth gate signal EM2 of a second level voltage. Accordingly, the initialization voltage VINT may be transmitted to the second node N2 and the pixel electrode of the organic light-emitting element OLED. Because the seventh transistor T7 is turned off by a fourth gate signal EM1 of a first level voltage, and the current path between the second terminal of the first transistor T1 and the second node N2 is blocked, the voltage of the second terminal of the first transistor T1 is maintained at the voltage (VREF-Vth+(C3/C4)×(VGH-VGL)) of the second terminal of the first transistor T1 during the second period P2, and the first transistor T1 may be kept turned off. In this case, in response to the voltage change amount of the second node N2, the voltage of the first node N1 may be a voltage ((1-α)Vdata+(α-1)VREF+VINT+Vth) that changes according to a capacity ratio α of the first capacitor Cst and the second capacitor Chold.

During the fifth period P5, through the seventh transistor T7 that are turned on according to a fourth gate signal EM1 of a second level voltage, and the sixth transistor T6 that is turned on according to a fifth gate signal EM2 of a second level voltage, the driving current (Id ∝ (Vgs-Vth)²) output by the first transistor T1 may flow through the organic light-emitting element OLED, and the organic light-emitting element OLED may emit light at a brightness corresponding to the driving current.

Because the first transistor T1 is turned off by the third capacitor Cboost prior to the third period P3, and the first transistor T1 is kept turned off during the third period P3, the voltage change of the second terminal of the first transistor T1 and the voltage change of the second node N2 may be reduced, and thus the brightness deviation and color mixing between pixels to which the same data signal DATA is written may be reduced.

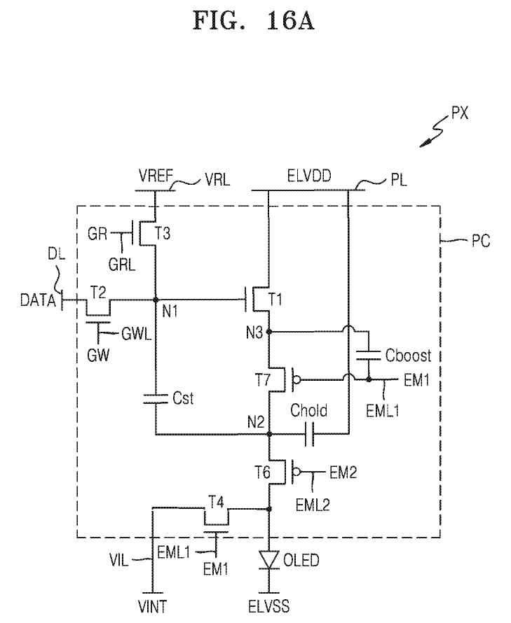

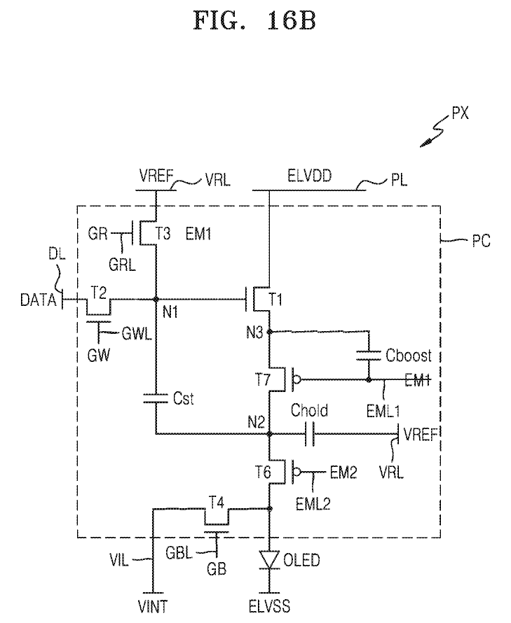

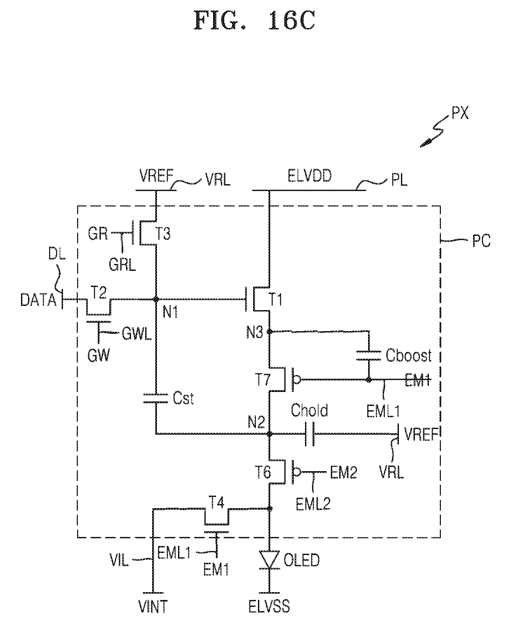

FIGS. 16A to 16C are schematic equivalent circuit diagrams of an embodiment of a pixel PX. The pixels PX shown in FIGS. 16A to 16C are modified embodiments of the pixel PX shown in FIG. 14. Hereinafter, differences are mainly described.

The pixel PX shown in FIG. 16A is different from the pixel PX shown in FIG. 14 in that the gate of the fourth transistor T4 is connected to the fourth gate line EML1. The gate of the fourth transistor T4 may receive a fourth gate signal EM1 from the fourth gate line EML1. Because, in the display device to which the pixel PX shown in FIG. 16A is applied, the third driving circuit 135 (refer to FIG. 2) may be omitted, the size of the peripheral area PA may be reduced.

During the fourth period P4, the fourth transistor T4 is turned on according to a fourth gate signal EM1 of a first level voltage, and the initialization voltage VINT may be transmitted to the second node N2 and the pixel electrode of the organic light-emitting element OLED.

The second capacitor Chold may be connected to the voltage source configured to supply a constant voltage to the second node N2. The constant voltage may be the first driving voltage ELVDD, the reference voltage VREF, the initialization voltage VINT, or the second driving voltage ELVSS. In an embodiment, as shown in FIG. 14, the second capacitor Chold may be connected to the second node N2 and a voltage source (e.g., the driving voltage line PL or a first driving voltage ELVDD supplying line in the peripheral area PA, or the like) supplying the first driving voltage ELVDD. In an alternative embodiment, as shown in FIG. 16B, the second capacitor Chold may be connected to the second node N2 and a voltage source (e.g., the reference voltage line VRL or a reference voltage VREF supplying line in the peripheral area PA, or the like) supplying the reference voltage VREF.

Although not shown, the second capacitor Chold may be connected to the second node N2 and a voltage source (e.g., the initialization voltage line VIL or an initialization voltage VINT supplying line in the peripheral area PA, or the like) supplying the initialization voltage VINT. In an alternative embodiment, the second capacitor Chold may be connected to the second node N2 and a voltage source (e.g., an opposite electrode or a second driving voltage ELVSS supplying line, or the like in the peripheral area PA) supplying the second driving voltage ELVSS.

The pixel PX shown in FIG. 16C is an embodiment in which the gate of the fourth transistor T4 is connected to the fourth gate line EML1, and the second capacitor Chold is connected to the second terminal of the seventh transistor T7 and the reference voltage line VRL among constant voltage sources.

FIG. 17 is a schematic equivalent circuit diagram of an embodiment of a pixel PX. The pixel PX shown in FIG. 17 is a modified embodiment of the pixel PX shown in FIG. 14. Hereinafter, differences are mainly described.

The pixel PX shown in FIG. 17 is different from the pixel PX shown in FIG. 14 in that the third capacitor Cboost is connected to the first transistor T1 and the second transistor T2. A first electrode of the third capacitor Cboost may be connected to the third node N3 to which the second terminal of the first transistor T1 is connected, and a second electrode of the third capacitor Cboost may be connected to the first gate line GWL to which the gate of the second transistor T2 is connected.

Unlike FIG. 15, the sixth period P6 during which to the pixel PX shown in FIG. 17 is operated may overlap the third period P3. During the third period P3 and the sixth period P6, the second transistor T2 may be turned on according to a first gate signal GW of a first level voltage. A voltage Vdata corresponding to a data signal may be transmitted to the gate of the first transistor T1 via the second transistor T2 that is turned on. In response to the voltage change amount of the first node N1, the voltage of the second node N2 may become a voltage (VREF-Vth+α×(Vdata-VREF)) changed according to the capacity ratio (α=C1/(C1+C2)) of the first capacitor Cst and the second capacitor Chold. The first capacitor Cst may be charged with the threshold voltage Vth of the first transistor T1 and the voltage Vdata corresponding to the data signal DATA.

The seventh transistor T7 is turned off according to a fourth gate signal EM1 of a first level voltage, and as a first gate signal GW transitions from a first level voltage to a second level voltage, due to coupling of the third capacitor Cboost, the voltage of the second terminal of the first transistor T1 may be changed by the voltage change amount (VGH-VGL) of a first gate signal GW and a capacitance ratio (C3/C4) of the third capacitor Cboost and the parasitic capacitor Csource formed at the second terminal of the first transistor T1. Here, the high level voltage VGH may be a first level voltage of a first gate signal GW, and the low level voltage VGL may be a second level voltage of a first gate signal GW.

The first transistor T1 may be turned off, the voltage of the second terminal of the first transistor T1 may be (VREF-Vth+(C3/C4)×(VGH-VGL)), and the gate-source voltage Vgs of the first transistor T1 may be a difference (Vgs=(C3/C4)×(VGL-VGH)+Vth) between the voltage (Vdata-VREF) of the gate of the first transistor T1 and the voltage (VREF-Vth+(C3/C4)×(VGH-VGL)) of the second terminal of the first transistor T1. The gate-drain voltage Vgd of the first transistor T1 may be the difference (Vdata-ELVDD) between the voltage Vdata corresponding to the data signal DATA and the voltage of the first terminal of the first transistor T1 (i.e., the first driving voltage ELVDD). Because the gate-source voltage Vgs of the first transistor T1 and the gate-drain voltage Vgd of the first transistor T1 are values less than 0, the first transistor T1 may be turned off.

Because, during the first period P1, the second period P2, the fourth period P4, and the fifth period P5, the operation of the pixel PX shown in FIG. 17 is the operation of the pixel PX shown in FIG. 14 described with reference to FIG. 15, description thereof is omitted.

In another embodiment, as shown in FIG. 16A, in the pixel PX shown in FIG. 17, the gate of the fourth transistor T4 may be connected to the fourth gate line EML1, and the gate of the fourth transistor T4 may receive a fourth gate signal EM1 from the fourth gate line EML1.

In another embodiment, as shown in FIG. 16B, in the pixel PX shown in FIG. 17, the second capacitor Chold may be connected to a voltage source configured to supply a constant voltage to the second node N2. The constant voltage may be the first driving voltage ELVDD, the reference voltage VREF, the initialization voltage VINT, or the second driving voltage ELVSS.

In another embodiment, as shown in FIG. 16C, in the pixel PX shown in FIG. 17, the gate of the fourth transistor T4 may be connected to the fourth gate line EML1, and the second capacitor Chold may be connected to the second terminal of the seventh transistor T7 and the voltage source configured to supply a constant voltage.

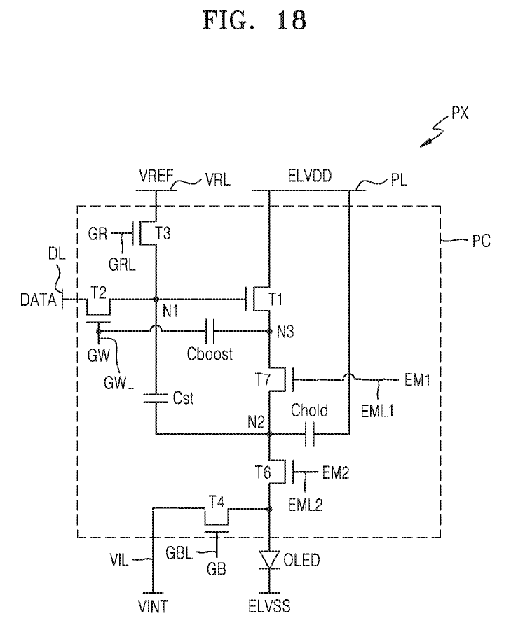

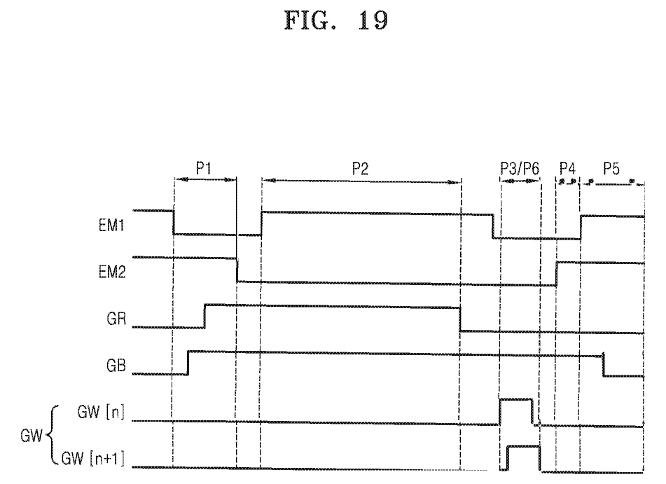

FIG. 18 is a schematic equivalent circuit diagram of an embodiment of a pixel PX. FIG. 19 is a timing diagram to explain an operation of a pixel PX shown in FIG. 18. The pixel PX shown in FIG. 18 is a modified embodiment of the pixel PX shown in FIG. 17.

The pixel PX shown in FIG. 18 is different from the pixel PX shown in FIG. 17 in that the sixth transistor T6 and the seventh transistor T7 are N-channel transistors. Because, in the pixels PX shown in FIG. 18, the sixth transistor T6 and the seventh transistor T7 are N-channel transistors, as shown in FIG. 19, the waveforms of a fourth gate signal EM1 and a fifth gate signal EM2 may be opposite to the waveforms of a fourth gate signal EM1 and a fifth gate signal EM2 shown in FIG. 15. Because the operation of the pixel PX shown in FIG. 18 is the same as the operation of the pixel PX shown in FIG. 17 described with reference to FIG. 15, description thereof is omitted.

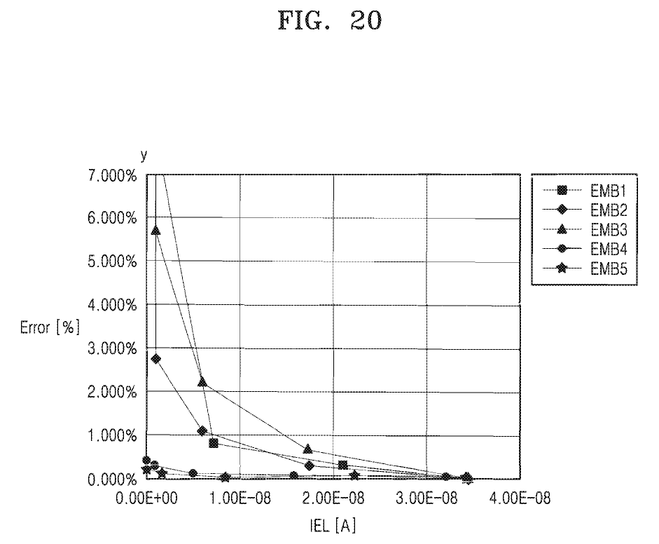

FIG. 20 is a diagram showing an embodiment of a brightness deviation of pixels PX.

FIG. 20 is a graph showing brightness deviation degrees for each brightness for each of a display device EMB1 employing the pixel PX shown in FIG. 4, a display device EMB2 employing the pixel PX shown in FIG. 7, a display device EMB3 employing the pixel PX shown in FIG. 8, a display device EMB4 employing the pixel PX shown in FIG. 9, and a display device EMB5 employing the pixel PX shown in FIG. 14. An x axis in the graph represents the driving currents IEL corresponding to brightnesses, and a y axis represents errors corresponding to brightness deviation degrees. It shows that a brightness deviation is reduced in a relatively low brightness in the order of the display device EMB1 employing the pixel PX shown in FIG. 4, the display device EMB2 employing the pixel PX shown in FIG. 7, the display device EMB3 employing the pixel PX shown in FIG. 8, the display device EMB4 employing the pixel PX shown in FIG. 9, and the display device EMB5 employing the pixel PX shown in FIG. 14.

In the pixels in embodiments, because charge introduced from the first terminal of the first transistor T1 to the second terminal of the first transistor T1 during a data-write period is blocked and thus a deviation due to charge sharing is reduced, the display device with an improved brightness deviation may be provided.

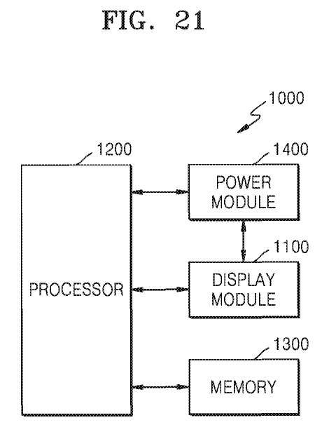

FIG. 21 is a block diagram of an embodiment of an electronic device 1000.

Referring to FIG. 21, the electronic device 1000 in an embodiment may include a display module 1100, a processor 1200, a memory 1300, and a power module 1400.

The electronic device 1000 may output various pieces of information through the display module 1100 within an operating system.

The processor 1200 may include at least one of a central processing unit (“CPU”), an AP, a graphic processing unit (“GPU”), a communication processor (“CP”), an image signal processor (“ISP”), and a controller. In an embodiment, the processor 1200 may be divided into two or more portions in a functional or structural viewpoint. In an embodiment, the processor 1200 may include a main processor in the form of a first driving chip, including a central processing unit, and an auxiliary processor in the form of a second driving chip, including a controller, wherein the auxiliary processor receives image signals from the main processor and processes the image signals to match interface specifications of the display module 1100.

The memory 1300 may include at least one of a non-volatile memory and a volatile memory. The memory 1300 may store data information desired for operations of the processor 1200 or the display module 1100. When the processor 1200 executes an application stored in the memory 1300, an image data signal and/or an input control signal may be transferred to the display module 1100, and the display module 1100 may process a provided signal and output image information through a display screen.

The power module 1400 may include a power supply module such as a power adapter or a battery unit, and a power converting module converting power supplied by the power supply module and generating power desired for operations of the electronic device 1000. Power conversion by the power converting module may include direct current to direct current (“DC-DC”) conversion, alternating current to direct current (“AC-DC”) conversion, and direct current to alternating current (“DC-AC”) conversion and is not limited thereto.

At least one of elements of the electronic device 1000 may be included in the display device in the embodiments. In addition, some of individual modules functionally included in one module may be included in the display device, and some other may be provided separately from the display device. In an embodiment, the display device may include the display module 1100 and the auxiliary processor of the processor 1200, and the main processor of the processor 1200, the memory 1300, and the power module 1400 may be provided in the form of another device within the electronic device 1000, not the display device. In another embodiment, the power module 1400 may be prepared in the display device, may provide power to the processor 1200 and the memory 1300 provided within the electronic device 1000 instead of the display device, and the disclosure is not limited thereto.

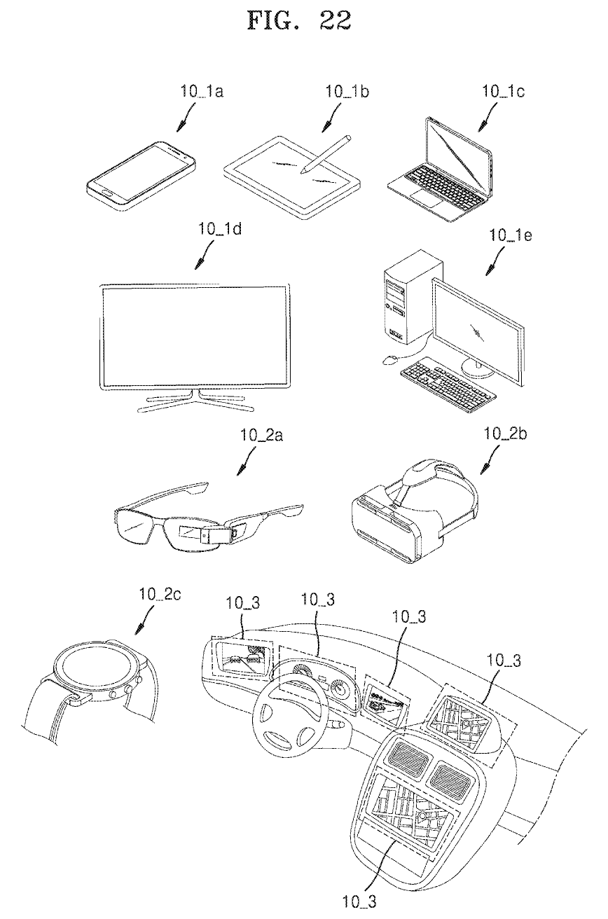

FIG. 22 is a schematic view of an embodiment of electronic devices.

A display device in embodiments is a device displaying moving images or still images and is applicable to various electronic devices. Referring to FIG. 22, the various electronic devices employing the display device in the embodiments may include not only electronic devices for displaying images, such as a smartphone 10_1a, a tablet personal computer 10_1b, a laptop computer 10_1c, a television (“TV”) 10_1d, and a desk monitor 10_1e, but also wearable electronic devices including a display module, such as a smart glasses 10_2a, a head mount display 10_2b, and a smart watch 10_2c, and vehicle electronic devices 10_3 including a display module, such as an instrument panel of an automobile, a center fascia, a center information display (“CID”) disposed on a dashboard, and a room mirror display. The electronic device in embodiments is not limited to the above-described devices.

The electronic device of FIG. 22 may include the elements shown in FIG. 21. In an embodiment, the smartphone 10_1a may include the display module 1100, the processor 1200, the memory 1300, and the power module 1400 shown in FIG. 21. The smartphone 10_1a may further include a battery device. Power provided by the battery device may be converted through the power module 1400 and provided to the processor 1200, the memory 1300, and the display module 1100. In an embodiment, the display device applied to the smartphone 10_1a may include the display module 1100 and further include the power module 1400. Although the processor 1200 and the memory 1300 may be provided in a form of a chip disposed (e.g., mounted) on a motherboard, which is an external device, the disclosure is not limited thereto.

By embodiments, the display device of a relatively high resolution with a reduced brightness deviation may be provided. However, the scope of the disclosure is not limited by this effect.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by those of ordinary skill in the art that various changes in form and details may be made therein without departing from the spirit and scope as defined by the following claims.

What is claimed is:

1. A pixel comprising:
a first transistor including:
a gate;
a first terminal connected to a first voltage line; and
a second terminal;
a second transistor connected to a data line and the gate of the first transistor;
a third transistor connected to the gate of the first transistor and a second voltage line;
a fourth transistor including:
a first terminal connected to the second terminal of the first transistor; and
a second terminal;

2. The pixel of claim 1, wherein the first transistor includes an N-channel transistor.

3. The pixel of claim 1, wherein a gate signal supplied to a gate of the second transistor and a gate signal supplied to a gate of the fifth transistor are the same to each other.

4. The pixel of claim 1, wherein a gate signal supplied to a gate of the fifth transistor has a same waveform as a gate signal supplied to a gate of the second transistor, and is a signal shifted forward or backward in time from the gate signal supplied to the gate of the second transistor.

5. The pixel of claim 1, wherein the constant voltage supplied by the voltage source to which the second capacitor is connected is a voltage supplied to the first voltage line.

6. The pixel of claim 1, wherein the constant voltage supplied by the voltage source to which the second capacitor is connected is a voltage supplied to the second voltage line.

7. The pixel of claim 1, wherein, during a data-write period in which the second transistor is turned on and a data signal from the data line is transmitted to the gate of the first transistor, the fourth transistor is turned off, and before the pixel emits light, the fifth transistor is turned on and the constant voltage is transmitted to the second terminal of the first transistor.

8. The pixel of claim 7, further comprising:
a sixth transistor connected to a light-emitting element and a third voltage line; and
a seventh transistor connected to the second terminal of the fourth transistor and the light-emitting element.

9. The pixel of claim 8, wherein a gate signal supplied to a gate of the fourth transistor and a gate signal supplied to a gate of the sixth transistor are the same to each other.

10. The pixel of claim 8, wherein the constant voltage supplied by the voltage source to which the second capacitor is connected is a voltage supplied to the third voltage line.

11. The pixel of claim 8, wherein one electrode of the light-emitting element is connected to the seventh transistor, and the constant voltage supplied by the voltage source to which the second capacitor is connected is a voltage supplied to another electrode of the light-emitting element.

12. A pixel comprising:
a first transistor including:
a gate;
a first terminal connected to a first voltage line; and
a second terminal;
a second transistor connected to a data line and the gate of the first transistor, the second transistor including:
a gate;
a third transistor connected to the gate of the first transistor and a second voltage line;
a fourth transistor including:
a gate;
a first terminal connected to the second terminal of the first transistor; and
a second terminal;
a first capacitor connected to the gate of the first transistor and the second terminal of the fourth transistor;
a second capacitor connected to the second terminal of the fourth transistor and a voltage source which supplies a constant voltage; and
a third capacitor connected to the second terminal of the first transistor, and the gate of the second transistor or the gate of the fourth transistor.

13. The pixel of claim 12, wherein the first transistor includes an N-channel transistor.

14. The pixel of claim 12, wherein the constant voltage supplied by the voltage source to which the second capacitor is connected is a voltage supplied to the first voltage line.

15. The pixel of claim 12, wherein the constant voltage supplied by the voltage source to which the second capacitor is connected is a voltage supplied to the second voltage line.

16. The pixel of claim 12, wherein the third capacitor is configured to raise a voltage of the second terminal of the first transistor according to a change in a voltage level of a gate signal supplied to the gate of the second transistor or a gate signal supplied to the gate of the fourth transistor, and
during a data-write period in which the second transistor is turned on and a data signal from the data line is transmitted to the gate of the first transistor, the first transistor is turned off.

17. The pixel of claim 16, wherein the pixel further comprising
a sixth transistor connected to a light-emitting element and a third voltage line; and
a seventh transistor connected to the second terminal of the fourth transistor and the light-emitting element.

18. An electronic device comprising:
a processor;
a controller configured to receive an on-operation signal from the processor and output a control signal based on the on-operation signal;
a gate driving circuit configured to receive the control signal and sequentially output at least one gate signal; and
a display panel in which a plurality of pixels are arranged, each of the plurality of pixels including:
a first transistor including:
a gate;
a first terminal connected to a first voltage line; and
a second terminal;
a second transistor connected to a data line and the gate of the first transistor;
a third transistor connected to the gate of the first transistor and a second voltage line;
a fourth transistor including:
a first terminal connected to the second terminal of the first transistor; and
a second terminal;
a control element connected to the second terminal of the first transistor;
a first capacitor connected to the gate of the first transistor and the second terminal of the fourth transistor; and
a second capacitor connected to the second terminal of the fourth transistor and a voltage source which supplies a constant voltage;

19. The electronic device of claim 18, wherein the control element includes a fifth transistor connected to the second terminal of the first transistor and the first voltage line.

20. The electronic device of claim 18, wherein the control element includes a third capacitor connected to the second terminal of the first transistor, and a gate of the second transistor or a gate of the fourth transistor.
